(19) United States
(12) Patent Application Publication
(10) Pub. No.: US 2013/0063001 A1
(43) Pub. Date: Mar. 14, 2013

(54) PIEZOELECTRIC DEVICE AND METHOD OF MANUFACTURING PIEZOELECTRIC DEVICE

(71) Applicants: TAKEHIRO TAKAHASHI, SAITAMA (JP); SHUICHI MIZUSAWA, SAITAMA (JP)

(72) Inventors: TAKEHIRO TAKAHASHI, SAITAMA (JP); SHUICHI MIZUSAWA, SAITAMA (JP)

(73) Assignee: NIHON DEMPA KOGYO CO., LTD., Tokyo (JP)

(21) Appl. No.: 13/594,880

(22) Filed: Aug. 27, 2012

(30) Foreign Application Priority Data
Sep. 12, 2011 (JP) 2011-198095

(51) Int. Cl. H01L 41/053; H01L 41/22

(52) U.S. Cl. 310/344; 29/25.35

(57) ABSTRACT

A piezoelectric device includes: a rectangular piezoelectric element formed of a piezoelectric material, the piezoelectric element having a rectangular excitation portion having an excitation electrode, a frame surrounding a circumference of the excitation portion, a connecting portion connecting one side of the rectangular excitation portion and the frame with a predetermined width; a base plate having a mounting face where a pair of external electrodes electrically connected to the excitation electrode are formed and a base bonding face bonded to one of principal faces of the frame; a lid plate bonded to the other principal face of the frame; and a bonding material for bonding the base plate, the frame, and the lid plate, wherein a trench having a length equal to or more than the predetermined width of the connecting portion is formed in at least one of the frame, the base plate, and the lid plate.

### CROSS-REFERENCE TO RELATED APPLICATIONS

This application claims the priority benefit of Japan application serial no. 2011-198095, filed on Sep. 12, 2011. The entirety of the above-mentioned patent application is hereby incorporated by reference herein and made a part of this specification.

### FIELD

This disclosure relates to a piezoelectric device having a trench formed in the vicinity of a connecting portion and a method of manufacturing the piezoelectric device.

### DESCRIPTION OF THE RELATED ART

There is known a piezoelectric element having an excitation portion which vibrates at a predetermined frequency. A piezoelectric device is formed by bonding a lid plate and a base plate using a bonding material on front and rear surface of the piezoelectric element. In such a piezoelectric device, the bonding material may be attached to an excitation portion when the lid plate, the base plate, and the frame of the piezoelectric element are bonded. In this regard, for example, Japanese Patent Publication No. H8-148961 discloses a piezoelectric device having a trench formed around the excitation portion. In the piezoelectric device disclosed in Japanese Patent Publication No. H8-148961, a trench is formed around the excitation portion, and the bonding material is gathered in the trench so as to prevent the bonding material from flowing to the excitation portion.

Further, there is known a piezoelectric device in which a frame surrounding the excitation portion is formed around the excitation portion, and the lid plate and the base plate are bonded to the front and rear surfaces of the frame using the bonding material. The excitation portion and the frame are connected to each other with a connecting portion, and a perforated trench penetrating the piezoelectric element is formed in the area other than the connecting portion between the excitation portion and the frame. In the piezoelectric device having such a perforated trench, the excessive bonding material flows to the perforated trench, and thus, the bonding material is not attached to the excitation portion.

However, the excessive bonding material is attached to the connecting portion in some cases. If the bonding material is attached to the connecting portion, flexibility of the connecting portion is degraded, thereby generating difficulty in bending. The connecting portion is bent to absorb the impact applied to the piezoelectric element. However, if the flexibility of the connecting portion is degraded, the impact resistance of the piezoelectric element is aggravated.

A need thus exists for a piezoelectric device having a trench for preventing the bonding material from making contact with the connecting portion and a method of manufacturing the piezoelectric device.

### SUMMARY

According to a first aspect of the disclosure, there is provided a piezoelectric device including: a piezoelectric element formed of a piezoelectric material in a rectangular shape, the piezoelectric element having a rectangular excitation portion having an excitation electrode, a frame surrounding a circumference of the excitation portion, a connecting portion connecting one side of the rectangular excitation portion and the frame with a predetermined width; a base plate having a mounting face where a pair of external electrodes electrically connected to the excitation electrode are formed and a base bonding face bonded to a first principal face of the frame; a lid plate bonded to a second principal face of the frame; and a bonding material applied in a paste state between the base plate and the frame and between the lid plate and the frame and then cured to bond the base plate, the frame, and the lid plate, wherein a trench having a length equal to or more than the predetermined width of the connecting portion is formed in the vicinity of the connecting portion in at least one of the frame, the base plate, and the lid plate.

According to another aspect of the disclosure, there is provided a method of manufacturing a piezoelectric device, including preparing a piezoelectric wafer having a plurality of piezoelectric elements formed of a piezoelectric material in a rectangular shape, the piezoelectric element having a rectangular excitation portion having an excitation electrode, a frame surrounding a circumference of the excitation portion, a connecting portion connecting one side of the rectangular excitation portion and the frame with a predetermined width; preparing a base wafer having a plurality of base plates, the base plate having a mounting face where a pair of external electrodes electrically connected to the excitation electrode are formed and a base bonding face bonded to a first principal face of the frame; preparing a lid wafer having a plurality of lid plates bonded to a second principal face of the frame; and bonding the base wafer, the piezoelectric wafer, and the lid wafer by applying a bonding material for bonding the base wafer, the piezoelectric wafer, and the lid wafer in a paste state between the base wafer and the piezoelectric wafer and between the lid wafer and the piezoelectric wafer, wherein a trench having a length equal to or more than the predetermined width of the connecting portion is formed in the vicinity of the connecting portion in at least one of the frame, the base plate, and the lid plate.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view illustrating a piezoelectric device 100;

FIG. 2A is a cross-sectional view taken along a line A-A of FIG. 1;

FIG. 2B is a cross-sectional view taken along a line B-B of FIG. 1;

FIG. 3A is a top plan view illustrating a piezoelectric element 130, where the +Y′-axis side face electrode is exposed;

FIG. 3B is a top plan view illustrating a piezoelectric element 130, where the −Y′-axis side face electrode is exposed;

FIG. 3C is a top plan view illustrating a base plate 120, where the −Y′-axis side face electrode is exposed;

FIG. 3D is a top plan view illustrating a base plate 120, where a mounting face electrode is exposed;

FIG. 4 is a flowchart illustrating a method of manufacturing a piezoelectric device 100;

FIG. 5 is a top plan view illustrating a piezoelectric wafer W130;

FIG. 6 includes both schematic diagram (right) and flow chart (left) of a method for manufacturing the piezoelectric wafer 130, wherein the schematic diagram includes six parts: (a), (b), (c), (d), (e) and (f), and each part corresponds to the steps of the flow chart of the manufacturing method;

FIG. 7 includes both schematic diagram (right) and flow chart (left) of the rest of processes of the method for manufacturing the piezoelectric wafer 130 in FIG. 6, wherein the schematic diagram includes five parts: (a), (b), (c), (d) and (e), and each part corresponds to the steps of the flow chart of the manufacturing method;

FIG. 8 is a top plan view illustrating a base wafer W120;

FIG. 9 includes both schematic diagram (right) and flow chart (left) of a method for manufacturing the base wafer 120 of FIG. 8, wherein the schematic diagram includes four parts: (a), (b), (c) and (d), and each part corresponds to the steps of the flow chart of the manufacturing method;

FIG. 10 includes both schematic diagram (right) and flow chart (left) of a portion of the rest of processes of the method for manufacturing the base wafer 120 in FIG. 9, wherein the schematic diagram includes four parts: (a), (b), (c) and (d), and each part corresponds to the steps of the flow chart of the manufacturing method;

FIG. 11 includes both schematic diagram (right) and flow chart (left) of the rest of processes of the method for manufacturing the base wafer 120 in FIG. 10, wherein the schematic diagram includes four parts: (a), (b), (c) and (d), and each part corresponds to the steps of the flow chart of the manufacturing method;

FIG. 12 is a top plan view illustrating a lid wafer W110;

FIG. 13A is a partially cross-sectional view illustrating a base wafer W120 where a bonding material 140 is applied;

FIG. 13B is a partially cross-sectional view illustrating a wafer where a base wafer W120 and a piezoelectric wafer W130 are bonded to each other;

FIG. 13C is a partially cross-sectional view illustrating a piezoelectric wafer W130 where a bonding material 140 is applied;

FIG. 13D is a partially cross-sectional view illustrating a wafer where a piezoelectric wafer W130 and a lid wafer W110 are bonded;

FIG. 14 is an exploded perspective view illustrating a piezoelectric device 200;

FIG. 15A is a top plan view illustrating a piezoelectric element 230;

FIG. 15B is a top plan view illustrating a base plate 220;

FIG. 15C is a cross-sectional view taken along a line D-D of FIG. 14;

FIG. 16A is a cross-sectional view illustrating a piezoelectric device 300;

FIG. 16B is a top plan view illustrating a lid plate 310;

FIG. 16C is a top plan view illustrating a base plate 320;

FIG. 17A is a cross-sectional view illustrating a piezoelectric device 400;

FIG. 17B is a top plan view illustrating a piezoelectric element 430;

FIG. 17C is a cross-sectional view illustrating a piezoelectric device 500;

FIG. 18A is a cross-sectional view illustrating a piezoelectric device 600;

FIG. 18B is a top plan view illustrating a piezoelectric element 630;

FIG. 18C is a cross-sectional view illustrating a piezoelectric device 700;

FIG. 19 is an exploded perspective view illustrating a piezoelectric device 800;

FIG. 20 is a cross-sectional view taken along a line E-E of FIG. 19;

FIG. 21A is a top plan view illustrating a piezoelectric element 830; and

FIG. 21B is a top plan view illustrating a base plate 820.

### DETAILED DESCRIPTION

Hereinafter, embodiments of this disclosure will be described in detail with reference to the accompanying drawings, which are not intended to limit the scope of the invention unless specified otherwise.

### First Embodiment

<Configuration of Piezoelectric Device 100>

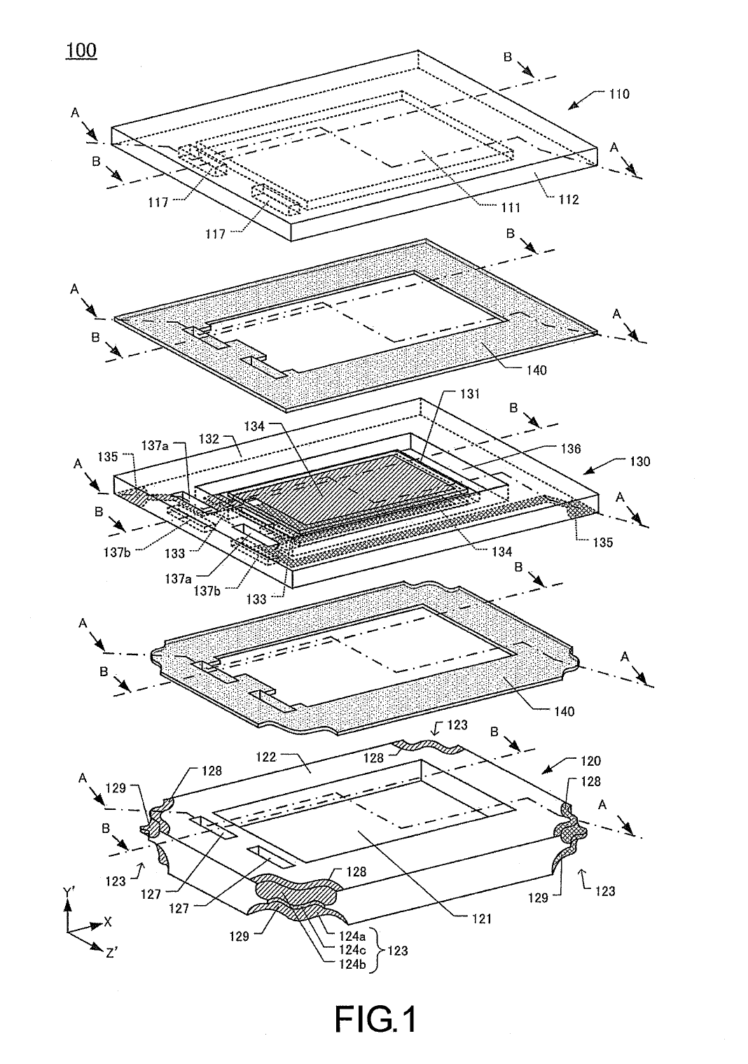

FIG. 1 is an exploded perspective view illustrating a piezoelectric device 100. The piezoelectric device 100 is a surface-mounted piezoelectric device, which is mounted on a print board and the like for use. The piezoelectric device 100 mainly includes a lid plate 110, a base plate 120, a piezoelectric element 130, and a bonding material 140. The lid plate 110 is made of, for example, ceramic, glass, piezoelectric material, and the like. The base plate 120 is made of, for example, a piezoelectric material such as a crystal material or glass. In addition, the piezoelectric element 130 is made of, for example, an AT-cut crystal material. The AT-cut crystal material has a principal face (YZ plane) passing through the X-axis and inclined by 35° 15′ from the Z-axis in the Y-axis direction of the crystal axes in the XYZ coordinate system. In the follow description, the axes y′ and z′ inclined with respect to the axis direction of the AT-cut crystal material are newly defined. Specifically, the longitudinal direction of the piezoelectric device 100 is defined as X-axis direction, the height direction of the piezoelectric device 100 is defined as a Y′-axis direction, and a direction perpendicular to the X and Y′ axes is defined as a Z′-axis direction.

The piezoelectric element 130 includes: an excitation portion 131 which vibrates at a predetermined frequency; a frame 132 formed to surround a periphery of the excitation portion 131; and a connecting portion 133 which connects the excitation portion 131 and the frame 132. A perforated trench 136 penetrating the piezoelectric element 130 in the Y′-axis direction is formed in the area excluding the connecting portion 133 between the excitation portion 131 and the frame 132. In addition, an excitation electrode 134 is formed in each of the +Y′-axis side face and the −Y′-axis side face of the excitation portion 131, and an extraction electrode 135 is extracted from each excitation electrode 134 to the frame 132. In addition, trenches 137a and 137b are formed in the +Y′-axis side face and the −Y′-axis side face, respectively, of the frame 132 in the vicinity of the connecting portion 133.

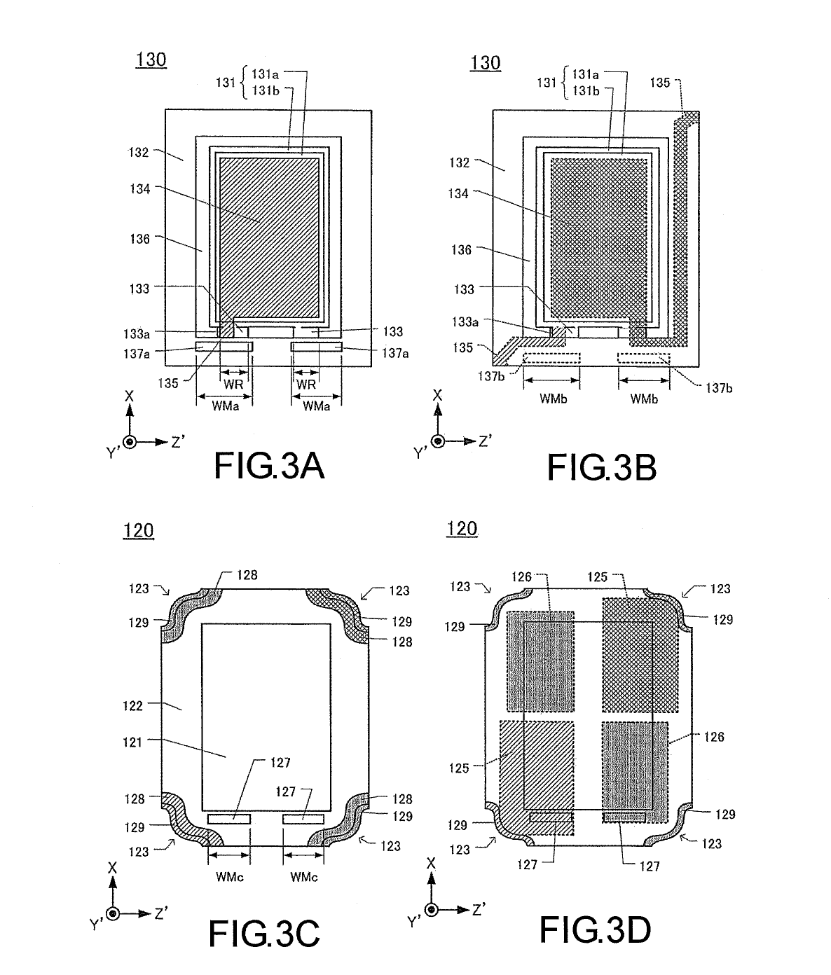

The base plate 120 is formed in a rectangular shape having a long side extending in the X-axis direction and a short side extending in the Z′-axis direction. The −Y′-axis side face of the base plate 120 is a mounting face where an external electrode 125 (refer to FIG. 3D) as an electrode electrically connected to a print board and the like through soldering and a ground terminal 126 (refer to FIG. 3D) for removing static electricity and the like charged in the piezoelectric device 100 are formed. In addition, a bonding material 140 is applied to the base bonding face 122 as the +Y′-axis side face of the base plate 120, which is bonded to the −Y′-axis side face of the frame 132 of the piezoelectric element 130. Furthermore, the base plate 120 is provided with a base hollow portion 121 hollowed in the −Y′-axis direction from the base bonding face 122, and the four corner of the base plate 120 are provided with castellated portions 123 castellated to the inside of the base plate 120. The castellated portion 123 is formed to extend along the long side and the short side of the base plate 120. The castellated portion 123 includes: a first face 124a outwardly extending to the base bonding face 122 side; a second face 124b which outwardly extends from the base bonding face 122 to the mounting face with an area smaller than that of the first face 124a; and a projecting face 124c outwardly projecting from the base plate 120 between the first and second faces 124a and 124b. The projecting face 124c is higher than the first and second faces 124a and 124b. In the area adjoining the castellated portion 123 of the base bonding face 122, a connection electrode 128 electrically connected to the extraction electrode 135 of the piezoelectric element 130 is formed. In addition, a lateral electrode 129 is formed in the castellated portion 123 and is electrically connected to the external electrode 125 and the connection electrode 128. Furthermore, a trench 127 hollowed from the base bonding face 122 is formed in the vicinity of the connecting portion 133 of the piezoelectric element 130 on the base bonding face 122 of the −X-axis side of the base hollow portion 121.

The lid plate 110 is formed in a rectangular shape having a long side extending in the X-axis direction and a short side extending in the Z′-axis direction. The −Y′-axis side face of the lid plate 110 is provided with a lid bonding face 112 bonded to the frame 132 of the piezoelectric element 130 using the bonding material 140. In addition, the lid plate 110 is provided with a lid hollow portion 111 hollowed in the +Y′-axis direction from the lid bonding face 112. The lid bonding face 112 in the −X-axis side of the lid hollow portion 111 is provided with a trench 117 hollowed in the +Y′-axis direction from the base bonding face 112 in the vicinity of the connecting portion 133 of the piezoelectric element 130.

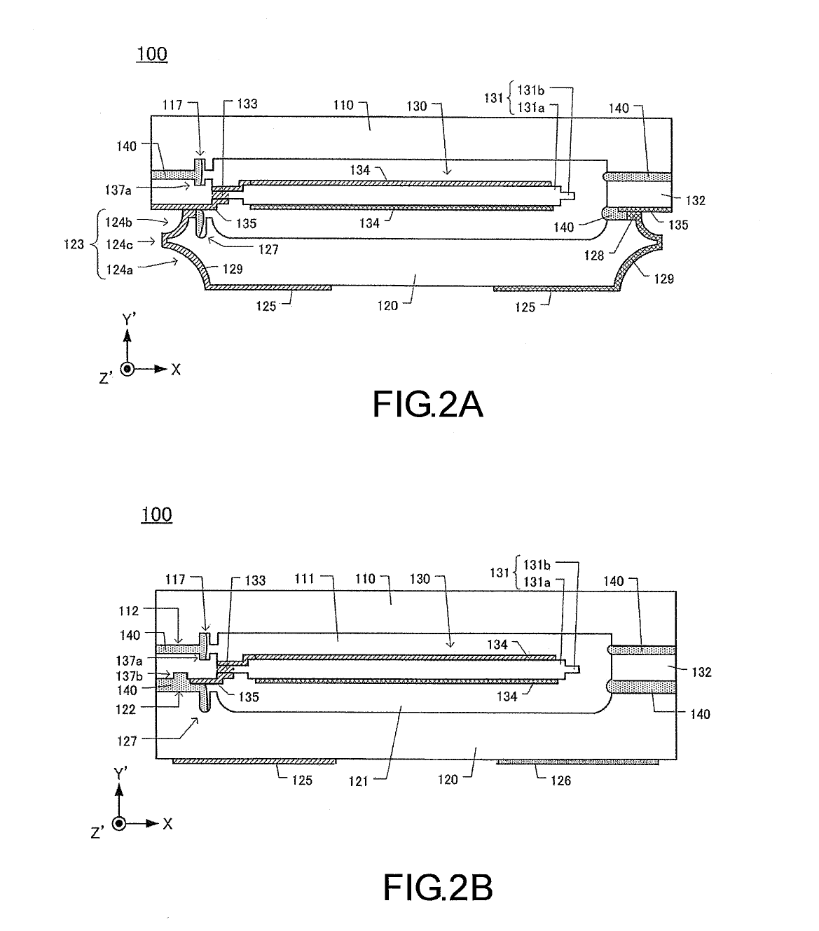

FIG. 2A is a cross-sectional view taken along a line A-A of FIG. 1. The excitation portion 131 of the piezoelectric element 130 includes a mesa-structure area 131a where the excitation electrode 134 is formed in the +Y′-axis side face and the −Y′-axis side face and a circumferential area 131b formed around the mesa-structure area 131a. The mesa-structure area 131a is thicker than the circumferential area 131b in the Y′-axis direction. The extraction electrode 135 is extracted from each of the excitation electrode 134 formed in the mesa-structure area 131a. Each extraction electrode 135 is extracted to the corner of the −Y′-axis side face of the frame 132 through the connecting portion 133. In addition, the lateral electrode 129 formed in the castellated portion 123 of the base plate 120 is electrically connected to the external electrode 125 and the connection electrode 128, and the extraction electrode 135 and the connection electrode 128 are electrically connected when the base plate 120 and the piezoelectric element 130 are bonded using the bonding material 140. Therefore, the excitation electrode 134 is electrically connected to the external electrode 125.

FIG. 2B is a cross-sectional view taken along a line B-B of FIG. 1. The trench 117 is formed in the vicinity of the connecting portion 133 of the lid bonding face 112 of the lid plate 110. The trench 117 has the same depth as that of the lid hollow portion 111, so that the bonding material 140 flows thereto. In addition, the trench 127 is formed in the vicinity of the connecting portion 133 of the base bonding face 122 of the base plate 120. The trench 127 has the same depth as that of the base hollow portion 121, so that the bonding material 140 flows thereto. Furthermore, the trenches 137a and 137b are formed in the +Y′-axis side face and the −Y′-axis side face, respectively, of the frame 132 of the piezoelectric element 130 in the vicinity of the connecting portion 133. Due to such trenches, it is possible to prevent the bonding material 140 from flowing to the connecting portion 133, in the piezoelectric device 100.

FIG. 3A is a top plan view illustrating the piezoelectric element 130, where the electrode of +Y′-axis side face is exposed. A pair of connecting portions 133 is connected to the −X-axis side of the excitation electrode 131 of the piezoelectric element 130. Each connecting portion 133 extends to the −X-axis direction from the excitation portion 131 and is connected to the frame 132. In addition, each trench 137a is formed in the vicinity of each connecting portion 133 in the +Y′-axis side face of the frame 132. Each trench 137a is formed in −X-axis side of each connecting portion 133. If the Z′-axis directional width of each connecting portion 133 is set to the width WR, and the Z′-axis directional width of the trench 137a is set to the width WMa, the width WMa is larger than the width WR. From the excitation electrode 134 formed in the +Y′-axis side face of the mesa-structure area 131a, the extraction electrode 135 is extracted to the +Y′-axis side face of the −Z′-axis side connecting portion 133. The extraction electrode 135 is further extracted to the −Y′-axis side face through the −Z′-axis side lateral face 133a of the connecting portion 133.

FIG. 3B is a top plan view illustrating the piezoelectric element 130 where the electrode of the −Y′-axis side face is exposed. In FIG. 3B, the electrode formed in the −Y′-axis side face and the trench are indicated by a dotted line. The excitation electrode 134 formed in the −Y′-axis side face of the mesa-structure area 131a is extracted to the −Y′-axis side face of the frame 132 through the −Y′-axis side face of the +Z′-axis side connecting portion 133. In addition, the excitation electrode 134 extends to the +Z′-axis direction and the +X-axis direction and is extracted to the +Z′-axis side corner and the +X-axis side corner of the −Y′-axis side face of the frame 132. In addition, the extraction electrode 135 extracted to the −Y′-axis side face through the −Z′-axis side lateral face 135a of the −Z′-axis side connecting portion 133 extends up to the −X-axis side lateral face in the −Z′-axis side of the frame 132. The trench 137b is formed in −Y′-axis side face of the frame 132 in the −X-axis side of each connecting portion 133. If the Z′-axis directional width of the trench 137b is set to the width WMb, the width WMb is larger than the width WR.

FIG. 3C is a top plan view illustrating the base plate 120 where the electrode of the −Y′-axis side face is exposed. The base bonding face 122 and the base hollow portion 121 hollowed to the −Y′-axis side from the base bonding face 122 are formed in the +Y′-axis side face of the base plate 120. The castellated portion 123 is formed in the lateral faces of four corners of the base plate 120, and the lateral electrode 129 is formed in the castellated portion 123. In addition, the connection electrode 128 is formed in the area adjoining the castellated portion 123 of the base bonding face 122, and the lateral electrode 129 and the connection electrode 128 are electrically connected. The trench 127 is formed in the −X-axis side of the base hollow portion 121. The trench 127 is formed in the −X-axis side of the connecting portion 133 of the piezoelectric element 130. If the Z′-axis directional width of the trench 127 is set to the width WMc, the width WMc is larger than the width WR.

FIG. 3D is a top plan view illustrating the base plate 120 where the electrode of the mounting face is exposed. In FIG. 3D, the electrode formed in the −Y′-axis side is indicated by a dotted line. The external electrode 125 is formed in the +Z′-axis side of the +X-axis side and the −Z′-axis side of the −X-axis side of the mounting face of the base plate 120 and is electrically connected to the lateral electrode 129. The ground terminal 126 is formed in the −Z′-axis side of the +X-axis side and the +Z′-axis side of the −X-axis side of the mounting face of the base plate 120.

<Method of Manufacturing Piezoelectric Device 100>

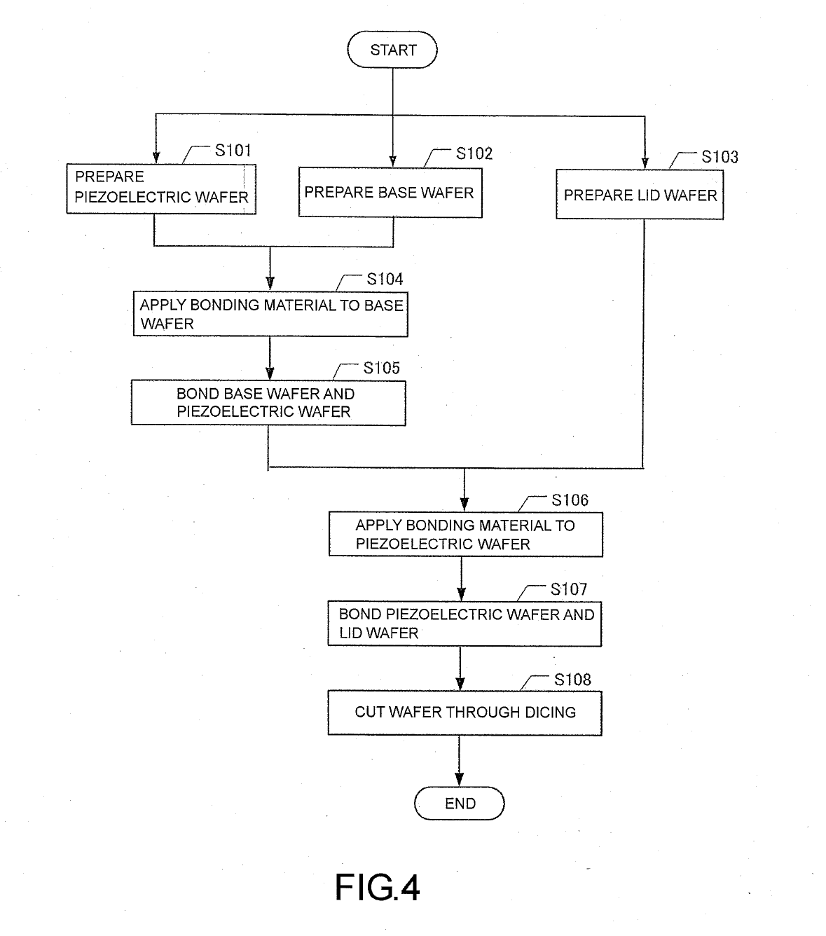

FIG. 4 is a flowchart illustrating a method of manufacturing the piezoelectric device 100. Hereinafter, the method of manufacturing a piezoelectric device 100 will be described with reference to FIG. 4.

In step S101, the piezoelectric wafer W130 is prepared. The piezoelectric wafer W130 is formed of a piezoelectric material, and a plurality of piezoelectric elements 130 are formed in the piezoelectric wafer W130.

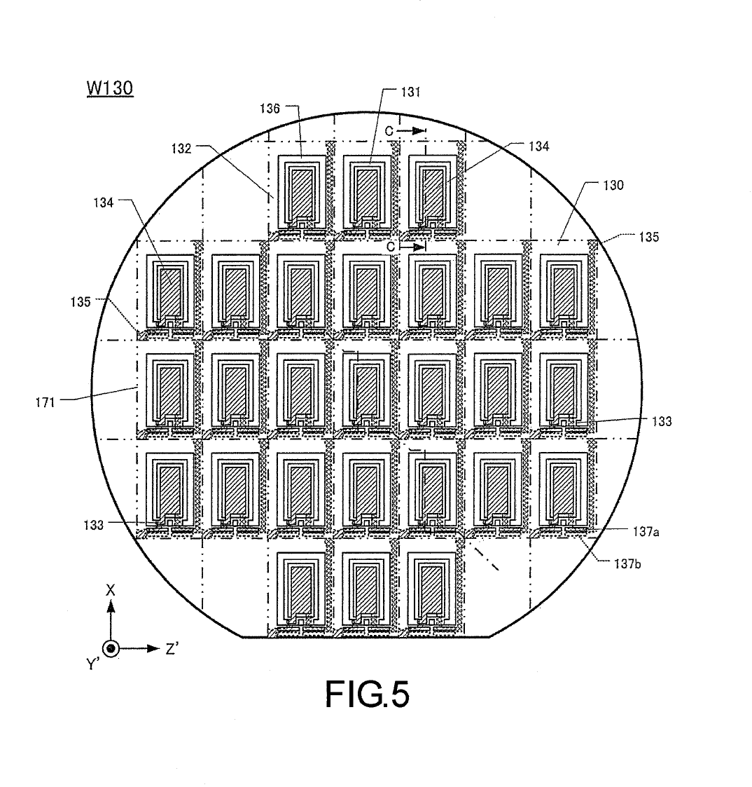

FIG. 5 is a top plan view illustrating the piezoelectric wafer W130. The piezoelectric elements 130 are formed in the piezoelectric wafer W130 in a matrix shape along the X-axis direction and the Z′-axis direction. In FIG. 5, a scribe line 171 which is a line for cutting the wafer in step S108 described below is indicated by a two-dotted chain line in the boundary between each of neighboring piezoelectric elements 130.

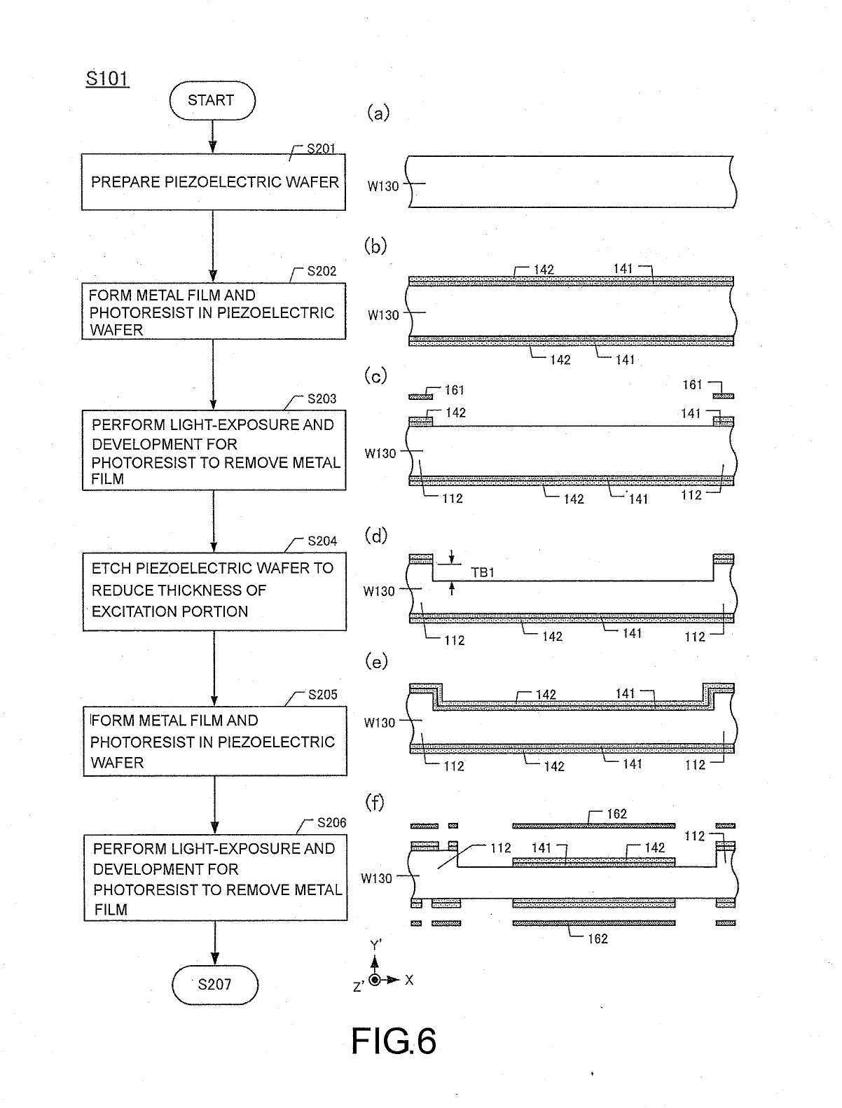

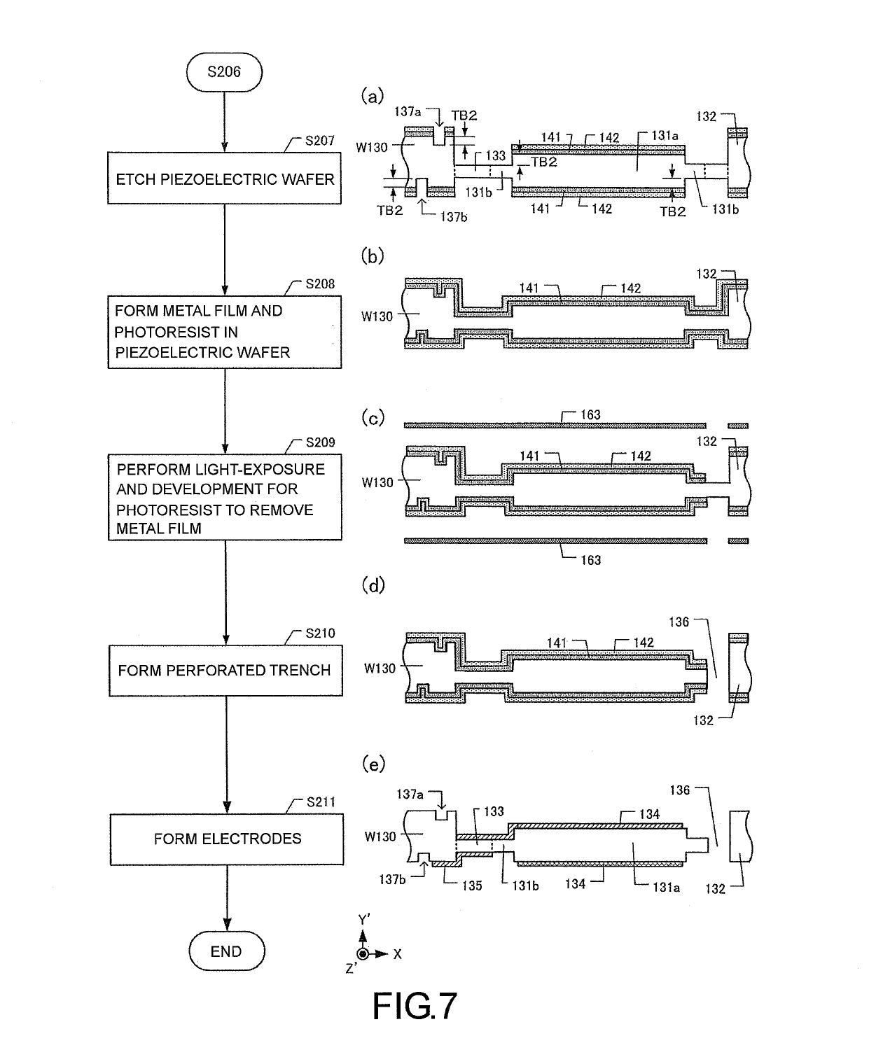

Hereinafter, a method of forming the piezoelectric element 130 in the piezoelectric wafer W130 will be described with reference to FIG. 6 to FIG. 7. FIG. 6 includes both schematic diagram (right) and flow chart (left) of a method for manufacturing the piezoelectric wafer 130, wherein the schematic diagram includes six parts: (a), (b), (c), (d), (e) and (f), and each part corresponds to the steps of the flow chart of the manufacturing method, and FIG. 7 includes the rest of the manufacturing method illustrated in FIG. 6. Namely, for the sake of convenience of description, for example, the steps in the left side of FIG. 6 respectively correspond to the schematic diagrams of the right side of FIG. 6, wherein part (a) of FIG. 6 corresponds to step S201, part (b) corresponds to step S202, part (c) corresponds to step S203 and part (d) corresponds to step S204, and so on. Such partially cross-sectional views of each part are cross-sectional views taken along the line C-C of FIG. 5.

In step S201 of FIG. 6, the piezoelectric wafer W130 is prepared. FIG. 6 part (a) is a partially cross-sectional view illustrating the piezoelectric wafer W130 prepared in step S201. In the piezoelectric wafer W130 prepared in step S201, the +Y′-axis side face and the −Y′-axis side face are formed flat. In the piezoelectric wafer W130, the surface roughness Ra of the +Y′-axis side face and the −Y′-axis side face is set to be equal to or lower than 100 angstroms.

In step S202, the metal film 141 and the photoresist 142 are formed in both the +Y′-axis side face and the −Y′-axis side face of the piezoelectric wafer W130. FIG. 6 part (b) is a partially cross-sectional view illustrating the piezoelectric wafer W130 where the metal film 141 and the photoresist 142 are formed. First, the metal film 141 is formed in the piezoelectric wafer W130 prepared in step S201. Further, the photoresist 142 is formed on the surface of the metal film 141. The metal film 141 is formed by performing sputtering, vacuum deposition, or the like for the metal film on the piezoelectric wafer W130. The metal film 141 is provided by, for example, forming a film of nickel (Ni), chrome (Cr), titanium (Ti), or nickel tungsten (NiW), and the like as a base film on the piezoelectric wafer W130 and forming a film of gold (Au), silver (Ag), and the like on the base film. The photoresist 142 is uniformly coated on the surface of the metal film 141 through spin coating, and the like.

In step S203, light-exposure and development are performed for the photoresist 142 to remove the metal film 141. FIG. 6 part (c) is a partially cross-sectional view illustrating the piezoelectric wafer W130 where light-exposure and development are performed for the photoresist 142 to remove the metal film 141. In step S203, first, the mask 161 is arranged in the +Y′-axis side face of the piezoelectric wafer W130, and the photoresist 142 is exposed to light and developed. Furthermore, the metal film 141 is removed through etching. In step S203, the metal film 141 is removed from the +Y′-axis side face in the area where the excitation portion 131, the perforated trench 136, and the connecting portion 133 are formed in the piezoelectric element 130.

In step S204, the piezoelectric wafer W130 is etched to reduce the thickness of the excitation portion 131. FIG. 6 part (d) is a partially cross-sectional view illustrating the piezoelectric wafer W130 etched to reduce the thickness of the excitation portion 131. The etching depth of the piezoelectric wafer W130 is set to the depth TB1. The etching of step S204 is performed at a high temperature of, for example, 90° C. using buffered hydrofluoric acid obtained by mixing hydrofluoric acid and ammonium fluoride. In a case where the etching is performed at a high temperature using the buffered hydrofluoric acid, it is possible to prevent the surface of the piezoelectric wafer W130 from being roughened and prevent generation of etch pits and the like. For this reason, it is possible to maintain the surface roughness Ra of the piezoelectric wafer W130 to be equal to or lower than 100 angstroms.

In step S205, the metal film 141 and the photoresist 142 are formed in the piezoelectric wafer W130. FIG. 6 part (e) is a partially cross-sectional view illustrating the piezoelectric wafer W130 where the metal film 141 and the photoresist 142 are formed. In step S205, the metal film 141 and the photoresist 142 remaining in step S204 are entirely removed, and the metal film 141 and the photoresist 142 are formed again in both the +Y′-axis side face and the −Y′-axis side face of the piezoelectric wafer W130.

In step S206, light-exposure and development are performed for the photoresist 142 to remove the metal film 141. FIG. 6 part (f) is a partially cross-sectional view illustrating the piezoelectric wafer W130 where light-exposure and development are performed for the photoresist 142 and the metal film 141 is removed. In step S206, light-exposure and development are performed for the photoresist 142 using the mask 162 to remove the metal film 141. The light-exposure area of the photoresist 141 in step S206 includes the trench 137a formed in the +Y′-axis side face of the frame 132, the trench 137b formed in the −Y′-axis side face of the frame 132, the circumferential area 131b, the perforated trench 136, and the connecting portion 133.

In step S207 of FIG. 7 part (a), the piezoelectric wafer W130 is etched. FIG. 7 part (a) is a partially cross-sectional view illustrating the etched piezoelectric wafer W130. In step S207, etching is performed for the area including the trench 137a formed in the +Y′-axis side face of the frame 132 of the piezoelectric wafer W130, the trench 137b formed in the −Y′-axis side face of the frame 132, the circumferential area 131b, the perforated trench 136, and the connecting portion 133. The etching is performed until a height difference TB2 is provided between the mesa-structure area 131a and the circumferential area 131b, and the depths TB2 is provided in the trench 137a formed in the +Y′-axis side face of the frame 132 and the trench 137b formed in the −Y′-axis side face of the frame 132.

In step S208, the metal film 141 and the photoresist 142 are formed in the piezoelectric wafer W130. FIG. 7 part (b) is a partially cross-sectional view illustrating the piezoelectric wafer W130 where the metal film 141 and the photoresist 142 are formed. In step S208, the metal film 141 and the photoresist 142 are entirely removed from the piezoelectric wafer W130 of FIG. 7A, and then the metal film 141 and the photoresist 142 are formed in the entire surfaces of the +Y′-axis side face and the −Y′-axis side face of the piezoelectric wafer W130.

In step S209, light-exposure and development are performed for the photoresist 142 to remove the metal film 141. FIG. 7 part (c) is a partially cross-sectional view illustrating the piezoelectric wafer W130 where light-exposure and development are performed for the photoresist 142 to remove the metal film 141. In step S209, the photoresist 142 is exposed to light using the mask 163. Furthermore, the photoresist 142 is developed, and the metal film 141 is removed to expose the piezoelectric material in the area where the perforated trench 136 is formed in the piezoelectric wafer W130 by removing the metal film 141.

In step S210, the perforated trench 136 is formed. FIG. 7 part (d) is a partially cross-sectional view illustrating the piezoelectric wafer W130 where the perforated trench 136 is formed. In step S210, the perforated trench 136 is formed in the piezoelectric wafer W130 by etching the piezoelectric wafer W130.

In step S211, the excitation electrode 134 and the extraction electrode 135 are formed. FIG. 7 part (e) is a partially cross-sectional view illustrating the piezoelectric wafer W130 where the excitation electrode 134 and the extraction electrode 135 are formed. After step S210, the metal film 141 and the photoresist 142 remaining in the piezoelectric wafer W130 are entirely removed, and then, the excitation electrode 134 and the extraction electrode 135 are formed in the piezoelectric wafer W130. The excitation electrode 134 and the extraction electrode 135 are provided by forming the metal film on the piezoelectric wafer W130 through sputtering, vacuum deposition, and the like. The excitation electrode 134 and the extraction electrode 135 are provided, for example, by forming a film of nickel (Ni), chrome (Cr), titanium (Ti), nickel-tungsten (NiW), and the like as a base film on the piezoelectric wafer W130 and forming a film of gold (Au) or silver (Ag) on the base film.

Returning to FIG. 4, in step S102, the base wafer W120 is prepared. A plurality of base plates 120 are formed in the base wafer W120. In the following description, it is assumed that the base wafer W120 and the base plate 120 are made of glass.

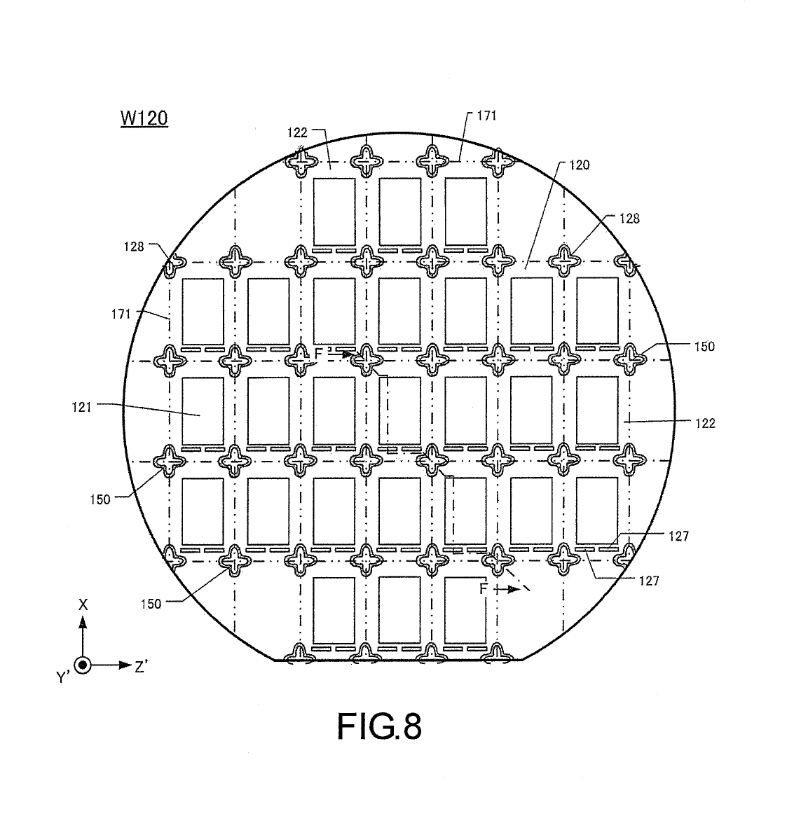

FIG. 8 is a top plan view illustrating the base wafer W120. The base plates 120 are formed in the base wafer W120 in a matrix shape along the X-axis direction and the Z′-axis direction. In FIG. 8, the scribe line 171 is indicated by a two-dotted chain line in the boundary between each neighboring base plate 120. A through-hole 150 penetrating the base wafer W120 in the Y′-axis direction and extending in the X-axis direction and the Z′-axis direction of the scribe line 171 is formed at the intersection of the scribe lines 171 extending in the X-axis direction and the Z′-axis direction. The through-hole 150 corresponds to the castellated portion 123 after the wafer is diced in step S108 as described below. In addition, the connection electrode 128 is formed around the through-hole 150 of the base bonding face 122. Furthermore, as illustrated in FIG. 3D, the lateral electrode 129 is formed in the lateral face of the through-hole 150, and the external electrode 125 and the ground terminal 126 are formed in the −Y′-axis side face of the base wafer W120.

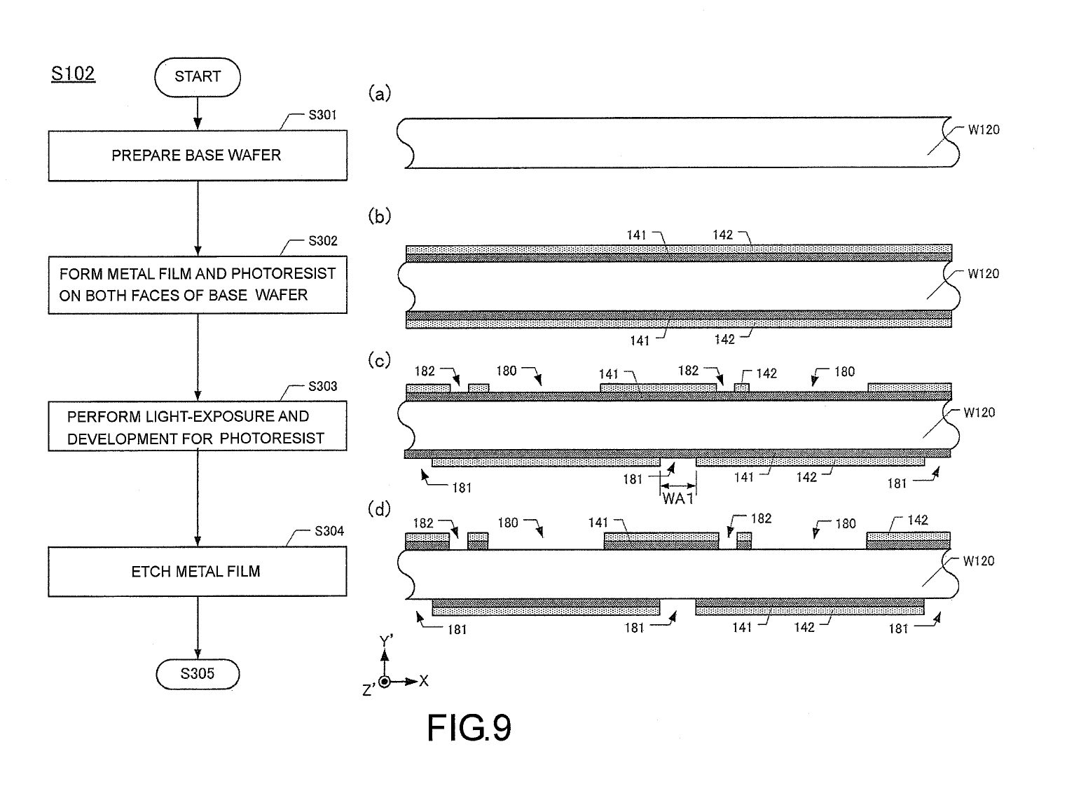

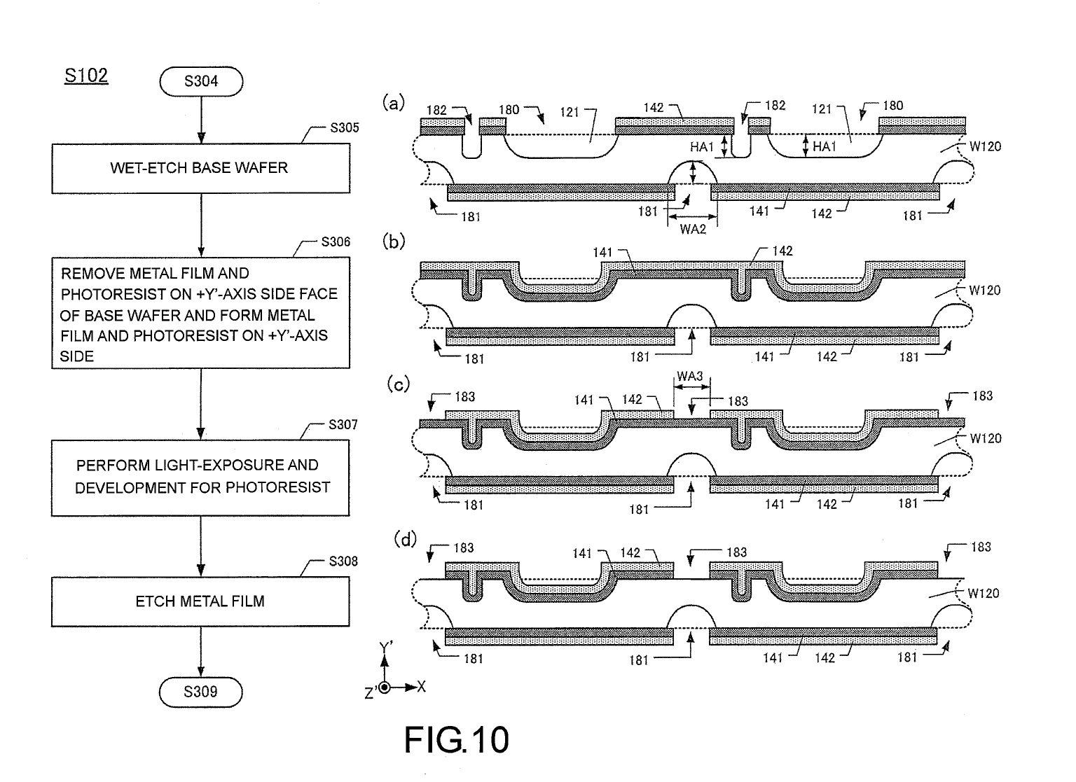

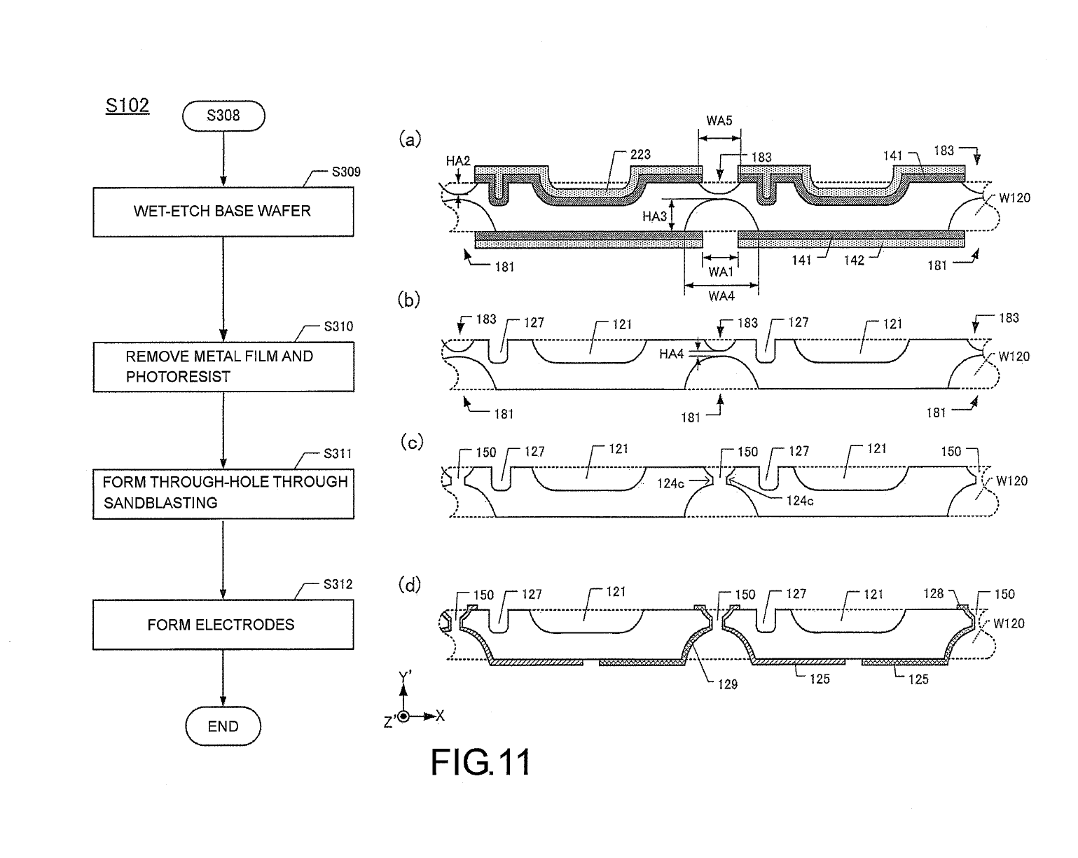

For the sake of convenience of description, FIG. 9 includes both schematic diagram (right) and flow chart (left) of a method for manufacturing the base wafer 120 of FIG. 8, wherein the schematic diagram includes four parts: (a), (b), (c) and (d), and each part corresponds to the steps of the flow chart of the manufacturing method, and FIG. 10 and FIG. 11 include the rest of the manufacturing method illustrated in FIG. 9. The partially cross-sectional views of each part are cross-sectional views taken along a line F-F of the base wafer W120 of FIG. 8. Hereinafter, a method of manufacturing the base wafer W120 will be described with reference to FIG. 9 to FIG. 11.

In step S301 of FIG. 9, the base wafer W120 is prepared. FIG. 9 part (a) is a partially cross-sectional view illustrating the base wafer W120 prepared in step S301. In the base wafer W120 prepared in step S301, the +Y′-axis side face and the −Y′-axis side face are formed in a flat plane shape as illustrated in FIG. 9 part (a).

In step S302, the metal film 141 and the photoresist 142 are formed in both the +Y′-axis side face and the −Y′-axis side face of the base wafer W120. FIG. 9 part (b) is a partially cross-sectional view illustrating the base wafer W120 where the metal film 141 and the photoresist 142 are formed. As illustrated in FIG. 9 part (b), the metal film 141 is formed in the +Y′-axis side face and the −Y′-axis side face of the base wafer W120, and the photoresist 142 is formed on the surface of the metal film 141.

In step S303, the photoresist 142 is exposed to light and developed. FIG. 9 part (c) is a partially cross-sectional view illustrating the base wafer W120 where light-exposure and development are performed for the photoresist 142. The portion where the photoresist 142 is exposed to light and developed in step S303 includes the hollow area 180 corresponding to the base hollow portion 121 (refer to FIG. 1) of the +Y′-axis side face of the base wafer W120, the perforation area 181 corresponding to the through-hole 150 of the −Y′-axis side face, and the trench area 182 corresponding to the trench 127 formed in the base bonding face 122. In a case where the base wafer W120 is made of glass, the area etched through wet etching of the base wafer W120 is widened. Therefore, the hollow area 180, the perforation area 181, and the trench area 182 are formed to be narrower than the base hollow portion 121, the trench 127, and the through-hole 150. In addition, if the X-axis directional width of the perforation area 181 is set to the width WA1, the width WA1 is preferably controlled not to cause the size of the through-hole 150 from excessively increasing.

In step S304, the metal film 141 is etched. FIG. 9 part (d) is a partially cross-sectional view illustrating the base wafer W120 where the metal film 141 is etched. In step S304, etching is performed to remove the metal films 141 of the hollow area 180, the trench area 182, and the perforation area 181 obtained by performing light-exposure and development for the photoresist 142 in step S303.

In step S305 of FIG. 10 part (a), the base wafer W120 is wet-etched. FIG. 10 part (a) is a partially cross-sectional view illustrating the wet-etched base wafer W120. In step S305, wet etching is performed by immersing the base wafer W120 including the hollow area 180, the trench area 182, and the perforation area 181 in the etchant until the hollow area 180, the trench area 182, and the perforation area 181 have a depth HA1. Since glass under the metal film 141 is also etched during the wet etching, for example, the X-axis directional width WA2 of glass etched in the perforation area 181 is wider than the X-axis directional width WA1 of the perforation area 181 (refer to FIG. 9 part (c)).

In step S306, the metal film 141 and the photoresist 142 in the +Y′-axis side face of the base wafer W120 are removed, and the metal film 141 is formed again in the entire surface of the +Y′-axis side face of the base wafer W120. The photoresist 142 is formed on the surface of the metal film 141. FIG. 10 part (b) is a partially cross-sectional view illustrating the base wafer W120 where the metal film 141 and the photoresist 142 are formed in the +Y′-axis side face. In FIG. 10 part (b), the metal film 141 and the photoresist 142 are formed in the entire surface of the +Y′-axis side face of the base wafer W120, and the glass corresponding to the perforation area 181 is exposed in the −Y′-axis side face of the base wafer W120.

In step S307, the photoresist 142 is exposed to light and developed. FIG. 10 part (c) is a partially cross-sectional view illustrating the base wafer W120 where the photoresist 142 of the +Y′-axis side face is exposed to light and developed. A portion of the photoresist 142 exposed to light and developed in step S307 includes the perforation area 183 corresponding to the through-hole 150 of the +Y′-axis side face. Similar to the hollow area 180, the trench area 182, and the perforation area 181, the wet-etched area of the base wafer W120 is widened. Therefore, the perforation area 183 is narrower than the width of the +Y′-axis side face of the through-hole 150. In addition, the X-axis directional width of the perforation area 183 is set to the width WA3.

In step S308, the metal film 141 is etched. FIG. 10 part (d) is a partially cross-sectional view illustrating the base wafer W120 where the metal film 141 is etched. In step S308, the metal film 141 formed in the perforation area 183 is etched and removed.

In step S309 of FIG. 11, the base wafer W120 is wet-etched. FIG. 11 part (a) is a partially cross-sectional view illustrating the base wafer W120 where glass is wet-etched. In step S309, wet etching is performed by immersing the exposed glass of the perforation area 181 and the perforation area 183 in the etchant so that the depth of the perforation area 181 is set to HA3, and the depth of the perforation area 183 is set to HA2. The depth HA3 of the perforation area 181 is set to a sum of the depths HA1 (refer to FIG. 10 part (a)) and HA2. As a result of the wet etching, the X-axis directional width of the wet-etched glass in the perforation area 183 is set to the width WA5, and the X-axis directional width of the wet-etched glass in the perforation area 181 is set to the width WA4. The width WA5 is larger than the width WA3 (refer to FIG. 10 part (c)), the width WA4 is larger than the width WA2 (refer to FIG. 10 part (a)), and the width WA4 is larger than the width WA5.

In step S310, the metal film 141 and the photoresist 142 are removed. FIG. 11 part (b) is a partially cross-sectional view illustrating the base wafer W120 where the metal film 141 and the photoresist 142 are removed. The base hollow portion 121 and the trench 127 are formed in the base wafer W120 in FIG. 11 part (b), and the thickness of glass in the position where the through-hole 150 is formed is set to the thickness HA4.

In step S311, the through-hole 150 is formed through sandblasting. FIG. 11 part (c) is a partially cross-sectional view illustrating the base wafer W120 where the through-hole 150 is formed through sandblasting. In step S311, the through-hole 150 is perforated through sandblasting, in which a grinding material is blasted onto the −Y′-axis side face of the base wafer W120, to form the projecting face 124c.

In step S312, electrodes are formed. FIG. 11 part (d) is a partially cross-sectional view illustrating the base wafer W120 where the electrodes are formed. In step S312, the connection electrode 128, the lateral electrode 129, the external electrode 125, and the ground terminal 126 are formed by performing sputtering, vacuum deposition, and the like for the metal film 141.

Returning to FIG. 4, in step S103, the lid wafer W110 is prepared. A plurality of lid plates 110 are formed in the lid wafer W110.

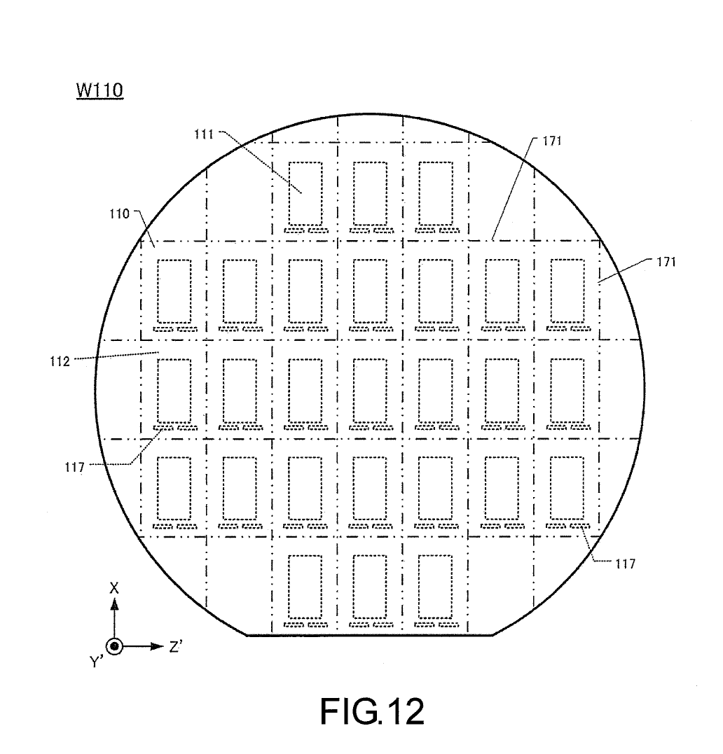

FIG. 12 is a top plan view illustrating the lid wafer W110. In the lid wafer W110, the lid plates 110 are formed in a matrix shape along the X-axis direction and the Z′-axis direction. In addition, in FIG. 12, the scribe line 171 is indicated by a two-dotted chain line in the boundary between each neighboring lid plates 110. The lid bonding face 112, the lid hollow portion 111, and the trench 117 are formed in the −Y′-axis side face of each lid plate 110. In the lid plate 110, the lid hollow portion 111 and the trench 117 are formed with the same depth. For this reason, the trench 117 and the lid hollow portion 111 can be formed simultaneously, so that it is not necessary to provide a process of forming only the trench 117.

In step S104, the bonding material 140 is applied to the base wafer W110.

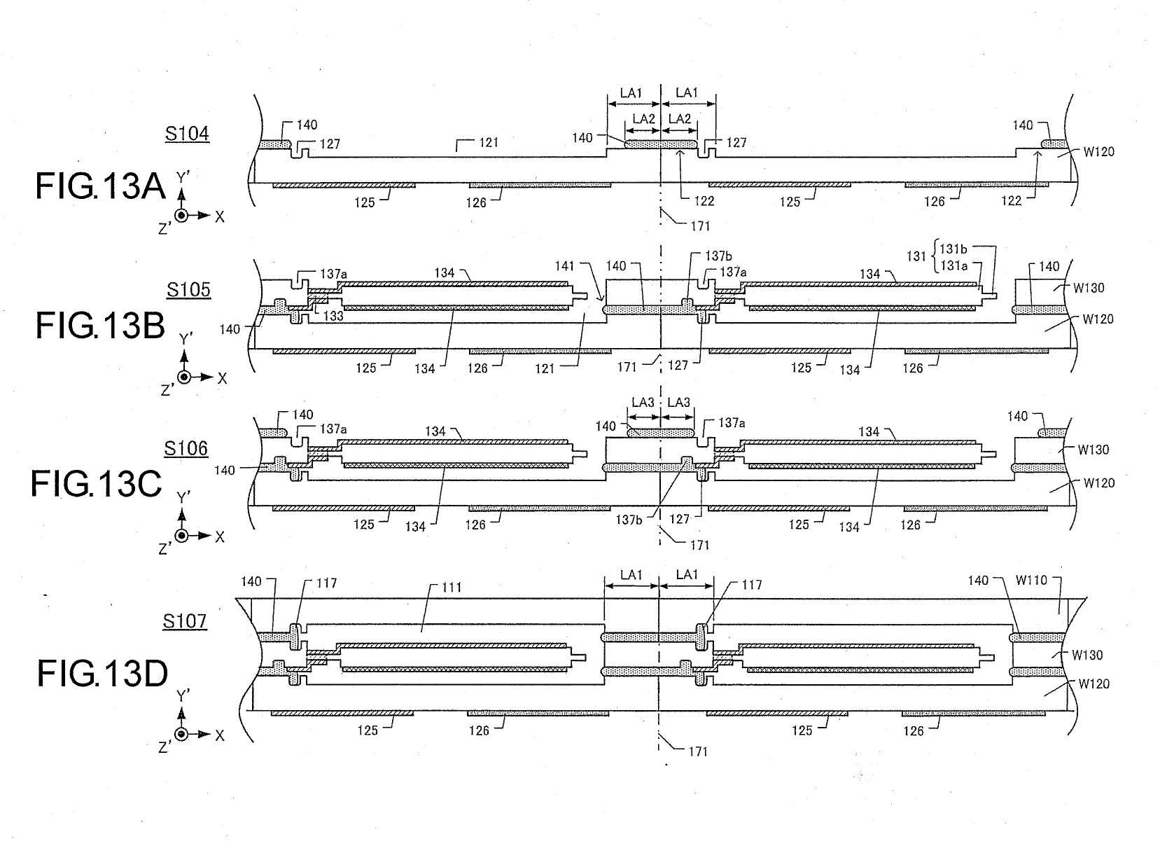

FIG. 13A is a partially cross-sectional view illustrating the base wafer W120 where the bonding material 140 is applied. FIG. 13A is a cross-sectional view illustrating the cross section corresponding to FIG. 2B. The bonding material 140 is applied to the base bonding face 122 of the base wafer W120. In the base plate 120, both the X-axis directional length of the base bonding face 122 in the +X-axis side of the base hollow portion 121 and the X-axis directional length of the base bonding face 122 in the −X-axis side of the base hollow portion 121 are set to the length LA1. In addition, both the X-axis directional length of the bonding material 140 applied to the +X-axis side of the base hollow portion 121 and the X-axis directional length of the bonding material 140 applied to the −X-axis side of the base hollow portion 121 are set to the length LA2.

In step S105, the base wafer W120 and the piezoelectric wafer W130 are bonded.

FIG. 13B is a partially cross-sectional view illustrating a wafer obtained by bonding the base wafer W120 and the piezoelectric wafer W130 to each other. The bonding material 140 applied to the base bonding face 122 of the base wafer W130 is widened within the X-Z′ plane by pressedly combining the base wafer W120 and the piezoelectric wafer W130. As a result, the bonding material 140 may generate extrusion 141 of the bonding material 140 in the base hollow portion 121. If such extrusion 141 is generated in the vicinity of the connecting portion 133, and the bonding material 140 is attached to the connecting portion 133, the impact resistance of the piezoelectric device 100 is degraded. Since the trenches 127 and 137b are formed in the vicinity of the connecting portion 133 in the piezoelectric device 100, the bonding material 140 flows to such trenches. Therefore, it is possible to prevent the bonding material 140 from being attached to the connecting portion 133.

In step S106, the bonding material 140 is applied to the piezoelectric wafer W130.

FIG. 13C is a partially cross-sectional view illustrating the piezoelectric wafer W130 where the bonding material 140 is applied. The bonding material 140 is applied to the +Y′-axis side face of the frame 132 of the piezoelectric wafer W130. Both the X-axis directional length of the bonding material 140 applied to the +X-axis side of the frame 132 and the X-axis directional length of the bonding material 140 applied to the −X-axis side of the frame 132 are set to the length LA3. The length LA3 may be equal to the length LA2.

In step S107, the piezoelectric wafer W130 and the lid wafer W110 are bonded.

FIG. 13D is a partially cross-sectional view illustrating a wafer obtained by bonding the piezoelectric wafer W130 and the lid wafer W110. The bonding is performed by pressedly combining the piezoelectric wafer W130 and the lid wafer W110. The bonding material 140 is widened within the X-Z′ plane by pressedly combining the piezoelectric wafer W130 and the lid wafer W110. In the piezoelectric device 100, the trench 117 is formed in the lid wafer W110, and the trench 137a is formed in the +Y′-axis side face of the frame 132 of the piezoelectric element 130. Therefore, the bonding material 140 enters the trenches when the bonding material 140 is widened within the X-Z′ plane. As a result, in the vicinity of the trench, it is possible to prevent the bonding material 140 from flowing over the lid hollow portion 111. Accordingly, it is possible to prevent the bonding material 140 from being attached to the connecting portion 133 formed in the vicinity of the trench.

In step S108, the wafer is cut through dicing. In step S108, individual piezoelectric devices 100 are formed by cutting the wafer obtained by bonding the lid wafer W110, the piezoelectric wafer W130, and the base wafer W120 to each other along the scribe line 171.

In the piezoelectric device, when the bonding material is applied to the connecting portion and is cured, the connecting portion is not bent easily. Therefore, the piezoelectric device is weakened by impact, and the impact resistance of the piezoelectric device is degraded. In addition, in a case where the amount of the applied bonding material is reduced in order to prevent the bonding material from being attached to the connecting portion, encapsulation of the piezoelectric device may be loosened in some cases. In the piezoelectric device 100, since the trench is formed in the vicinity of the connecting portion 133, it is possible to prevent the bonding material 140 from being attached to the connecting portion 133 without reducing the amount of the applied bonding material 140. In the trench formed in the piezoelectric device 100, it is not necessary to separately perform the process of forming the trench as described in the method of manufacturing the piezoelectric device 100. Therefore, it is preferable that the manufacturing can be made in the same sequence as the method of manufacturing the piezoelectric device having no trench.

In the piezoelectric device 100, the trench is formed only in the vicinity of the connecting portion 133. In this manner, in the piezoelectric device 100, the portion where the thickness of the external wall of the piezoelectric device 100 is reduced is limited. Therefore, it is possible to prevent decrease of the strength of the external wall of the piezoelectric device 100.

Furthermore, the crystal impedance (CI) value of the piezoelectric element is degraded if parallelism between the surfaces of the +Y′-axis side and the −Y′-axis side of the mesa-structure area and the surfaces of the +Y′-axis side and the −Y′-axis side of the circumferential area is degraded. In the piezoelectric element 130, the buffered hydrofluoric acid is used when the mesa-structure area 131a is formed so as not to aggravate the surface roughness of the excitation portion 131. Since the surface roughness is not aggravated, high surface parallelism is maintained between the mesa-structure area and the circumferential area. For this reason, in the piezoelectric element 130, it is possible to prevent degradation of the CI value caused by degradation of the parallelism between the mesa-structure area and the circumferential area. In the piezoelectric element 130, an excellent CI value can be obtained when the surface roughness Ra is equal to or lower than 100 angstroms.

### Second Embodiment

Various modifications of the piezoelectric device 100 are conceivable. Hereinafter, several modifications of the piezoelectric device 100 will be described. In the following description, like reference numerals denote like elements as in the piezoelectric device 100 described in the first embodiment, and description thereof will not be repeated.

<Configuration of Piezoelectric Device 200>

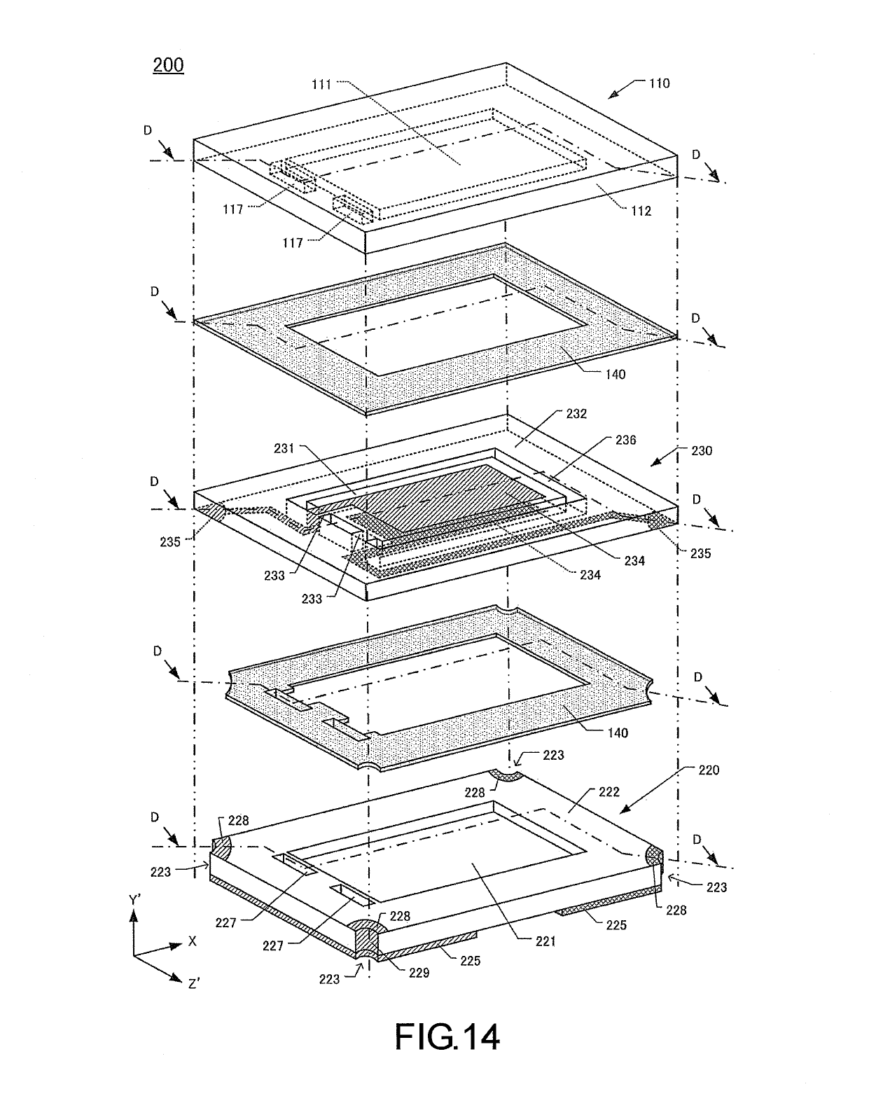

FIG. 14 is an exploded perspective view illustrating the piezoelectric device 200. The piezoelectric device 200 includes a lid plate 110, a base plate 220, and a piezoelectric element 230.

The piezoelectric element 230 includes: an excitation portion 231 which vibrates at a predetermined frequency; a frame 232 formed to surround a circumference of the excitation portion 231; and a pair of connecting portions 233 for connecting the excitation portion 231 and the frame 232. A pair of the connecting portions 233 is connected to the −X-axis side of the excitation portion 231 and extends in parallel with the X-axis direction from the excitation portion 231 so as to be connected to the frame 232. A perforated trench 236 penetrating the piezoelectric element 230 in the Y′-axis direction is formed in the area other than the connecting portion 233 between the excitation portion 231 and the frame 232. In addition, the excitation electrode 234 is formed in each of the +Y′-axis side face and the −Y′-axis side face of the excitation portion 231. The extraction electrode 235 is extracted from each excitation electrode 234 to the frame 232.

The base plate 220 is formed in a rectangular shape having a long side extending in the X-axis direction and a short side extending in the Z′-axis direction. The −Y′-axis side face of the base plate 220 is a mounting face where the external electrode 225 as an electrode for electrical connection through soldering onto a print board and the like is formed. In addition, the bonding material 140 is applied to the base bonding face 222, which is a +Y′-axis side face of the base plate 220, bonded to the −Y′-axis side face of the frame 232 of the piezoelectric element 230. In addition, the base hollow portion 221 hollowed in the −Y′-axis direction from the base bonding face 222 is formed in the base plate 220, and the castellated portion 223 castellated into the inside of the base plate 220 is formed in the lateral faces of four corners of the base plate 220. The connection electrode 228 electrically connected to the extraction electrode 235 of the piezoelectric element 230 is formed in the area adjoining the castellated portion 223 of the base bonding face 222. The lateral electrode 229 is formed in the castellated portion 223 and is electrically connected to the external electrode 225 and the connection electrode 228. Furthermore, the trench 227 hollowed from the base bonding face 222 is formed in the vicinity of each of a pair of the connecting portions 233 of the piezoelectric element 230 in the base bonding face 222 of the −X-axis side of the base hollow portion 221.

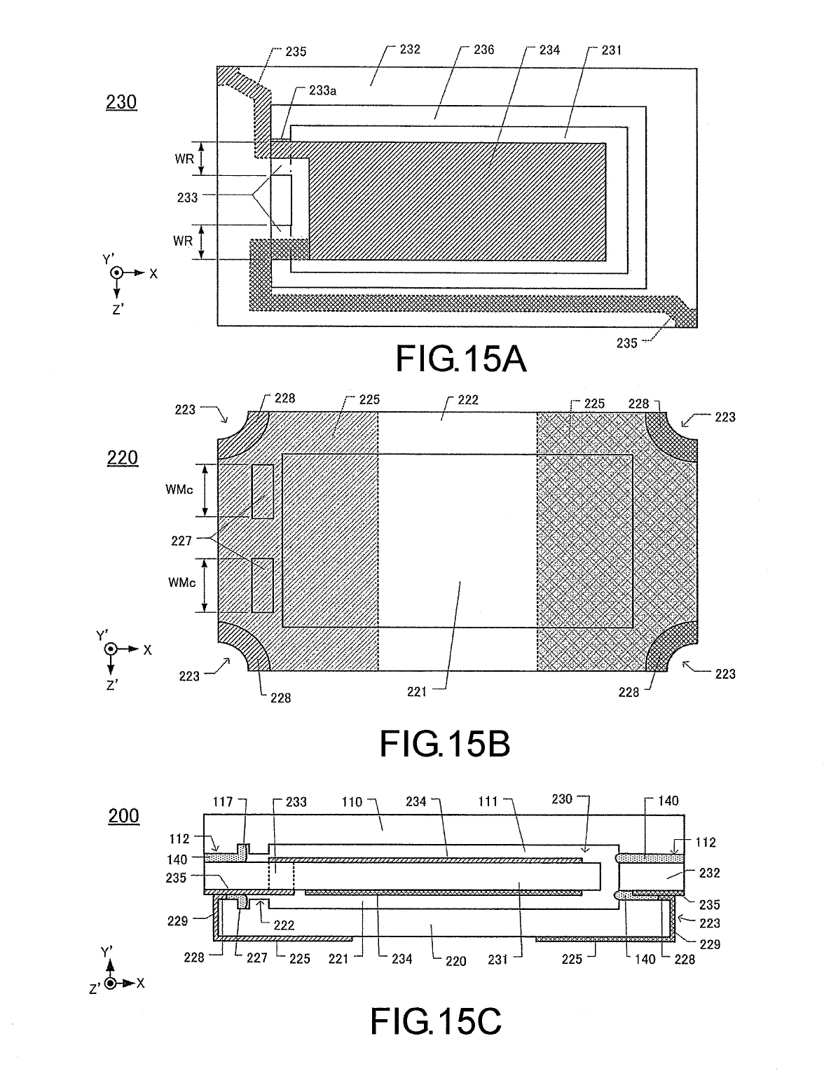

FIG. 15A is a top plan view illustrating the piezoelectric element 230. The piezoelectric element 230 includes: an excitation portion 234, a frame 232 surrounding the excitation portion 234; and a pair of connecting portions 233 for connecting the excitation portion 234 and the frame 232. Each connecting portion 233 is formed to have a width WR in the Z′-axis direction. From the excitation electrode 234 formed in the Y′-axis side face of the excitation portion 234, the frame 232 extends through the +Y′-axis side face of the connecting portion 233 of the −Z′-axis side, the lateral face 233a of the −Z′-axis side, and the −Y′-axis side face, so that the extraction electrode 235 is extracted to the −X-axis side corner of the −Z′-axis side of the frame 232. In addition, from the excitation electrode 234 formed in the −Y′-axis side face, the extraction electrode 235 is extracted to the +Z′-axis side corner of the +X-axis side of the frame 232 through the connecting portion 233 of the +Z′-axis side.

FIG. 15B is a top plan view illustrating the base plate 220. The external electrode 225 is formed in each of the +X-axis side and the −X-axis side in the −Y′-axis side face of the base plate 220, and the connection electrode 228 is formed around the castellated portion 223 of the base bonding face 222. A pair of trenches 227 is formed in the −X-axis side of the base hollow portion 221. Each trench 227 is formed in the −X-axis side of the connecting portion 233. The Z′-axis directional length WMc of the trench 227 is equal to or longer than the Z′-axis directional width WR of the connecting portion 223.

FIG. 15C is a cross-sectional view taken along a line D-D of FIG. 14. The piezoelectric element 230 is formed such that the Y′-axis directional thicknesses of the excitation portion 231, the connecting portion 233, and the frame 232 are equal to each other. In the base plate 220, the lateral electrode 229 formed in the lateral face of the castellated portion 223 is electrically connected to the connection electrode 228 formed in the base bonding face 222 and the external electrode 225 formed in the mounting face. Since the connection electrode 228 is electrically connected to the extraction electrode 235, the external electrode 225 is electrically connected to the excitation electrode 234. The depth of the trench 227 formed in the base bonding face 222 is equal to the depth of the base hollow portion 221 of the base plate 220. For this reason, the trench 227 and the base hollow portion 221 can be simultaneously formed in the same process. In addition, in the piezoelectric device 200, the trench 117 and the trench 227 are formed in the −X-axis side of the connecting portion 233. Therefore, it is possible to prevent the bonding material 140 from being attached to the connecting portion 223.

<Configuration of Piezoelectric Device 300>

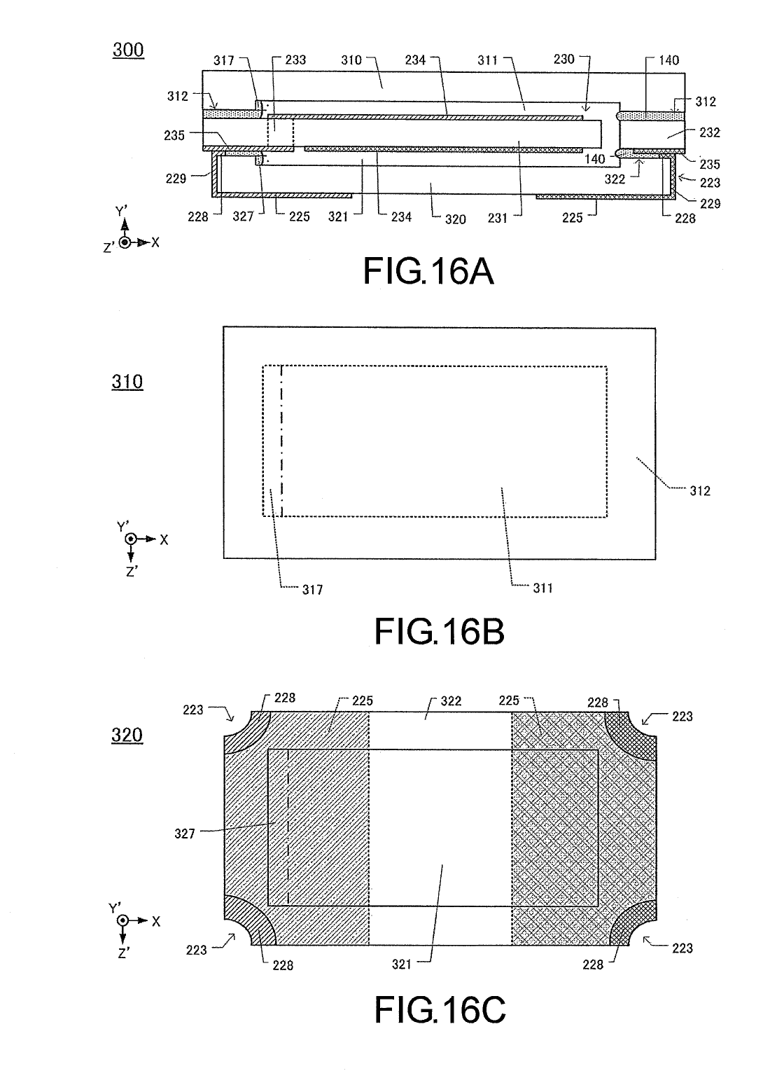

FIG. 16A is a cross-sectional view illustrating the piezoelectric device 300. FIG. 16A is a cross-sectional view taken along a line XVI-XVI of FIG. 14 for illustrating the piezoelectric device 300. The piezoelectric device 300 includes a lid plate 310, a base plate 230, and a piezoelectric element 230. A lid bonding face 312, a trench 317, and a lid hollow portion 311 hollowed in the +Y′-axis direction from the lid bonding face 312 are formed in the −Y′-axis side face of the lid plate 310. The lid plate 310 is bonded to the +Y′-axis side face of the frame 232 of the piezoelectric element 230 through the lid bonding face 312 using the bonding material 140. A base bonding face 322, a trench 327, and a base hollow portion 321 hollowed in the −Y′-axis direction from the base bonding face 322 are formed in the +Y′-axis side face of the base plate 320. The base plate 320 is bonded to the −Y′-axis side face of the frame 232 of the piezoelectric element 230 through the base bonding face 322 using the bonding material 140. The trench 317 of the lid plate 310 is formed in the −X-axis side of the connecting portion 233 and has the same depth as that of the lid hollow portion 311. The trench 327 of the base plate 320 is formed in the −X-axis side of the connecting portion 233 and has the same depth as that of the base hollow portion 321. The trench 317 and the lid hollow portion 311 may be formed simultaneously, and the trench 327 and the base hollow portion 321 may be formed simultaneously. The trenches 317 and 327 are connected to the lid hollow portion 311 and the base hollow portion 321, respectively. Due to the trenches 327 and 317 formed in the piezoelectric device 300, it is possible to prevent the bonding material 140 from being attached to the connecting portion 233.

FIG. 16B is a top plan view illustrating the lid plate 310. In the lid plate 310, the trench 317 and the lid hollow portion 311 are connected to each other. In addition, the Z′-axis directional widths of the trench 317 and the lid hollow portion 311 are equal to each other.

FIG. 16C is a top plan view illustrating the base plate 320. In the base plate 320, the trench 327 and the base hollow portion 321 are connected to each other. In addition, the Z′-axis directional widths of the trench 327 and the lid hollow portion 321 are equal to each other.

<Configuration of Piezoelectric Device 400>

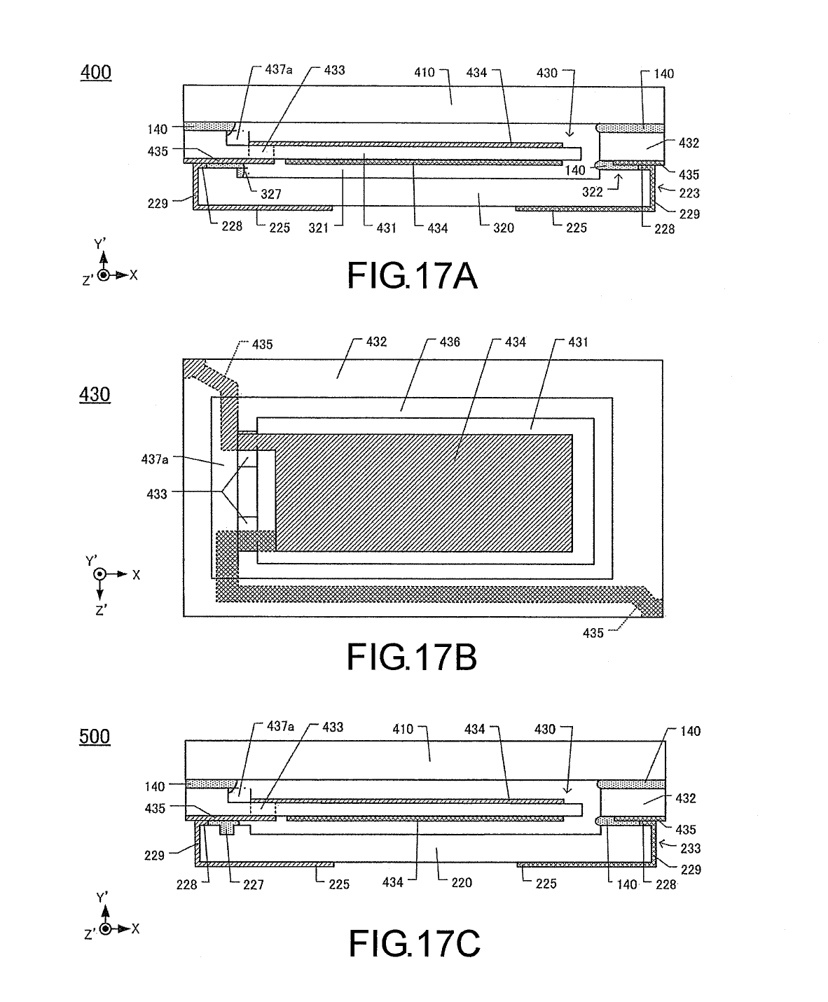

FIG. 17A is a cross-sectional view illustrating a piezoelectric device 400. FIG. 17A is a cross-sectional view taken along the line D-D of FIG. 14 for illustrating the piezoelectric device 400. The piezoelectric device 400 includes a lid plate 410, a base plate 320, and a piezoelectric element 430. The lid plate 410 has a flat panel shape in which both the +Y′-axis side face and the −Y′-axis side face are formed flat. The piezoelectric element 430 includes an excitation portion 431, a frame 432, and a connecting portion 433. An excitation electrode 434 is formed in the +Y′-axis side face and the −Y′-axis side face of the excitation portion 431. An extraction electrode 435 is extracted from each excitation electrode 434 through the connecting portion 433 to the frame 432. In addition, the extraction electrode 435 is electrically connected to the connection electrode 228 of the base plate 320. In the piezoelectric element 430, the excitation portion 431 and the connecting portion 433 have the same thickness, and the frame 432 is thicker than the excitation portion 431 and the connecting portion 433. The trench 437a is formed in the +Y′-axis side face of the frame 432. The trench 437a is formed in the area adjoining the connecting portion 433 of the frame 432. Since the thicknesses of the excitation portion 431, the connecting portion 433, and the frame 432 in the area where the trench 437a is formed are equal to each other, the trench 437a, the connecting portion 433, and the excitation portion 431 can be formed simultaneously. In the piezoelectric device 400, due to the trench 437a formed in the piezoelectric element 430 and the trench 327 formed in the base plate 220, it is possible to prevent the bonding material 140 from making contact with the connecting portion 433.

FIG. 17B is a top plan view illustrating the piezoelectric element 430. In the piezoelectric element 430, the excitation portion 431 and the frame 432 are connected to each other with a pair of connecting portions 433. In addition, the perforated trench 436 penetrating the piezoelectric element 430 in the Y′-axis direction is formed in the area other than the connecting portion 433 between the excitation portion 431 and the frame 432. The trench 437a formed in the area adjoining the connecting portion 433 in the +Y′-axis side face of the frame 432 has the same width as the Z′-axis directional width of the perforated trench 436 and is provided in the −X-axis side of the connecting portion 433.

<Configuration of Piezoelectric Device 500>

FIG. 17C is a cross-sectional view illustrating the piezoelectric device 500. FIG. 17C is a cross-sectional view taken along the line D-D of FIG. 14 for illustrating the piezoelectric device 500. The piezoelectric device 500 includes a lid plate 410, a base plate 220 (refer to FIG. 15C), and a piezoelectric element 430. In the piezoelectric device 500, due to the trench 437a formed in the piezoelectric element 430 and the trench 227 formed in the base plate 220, it is possible to prevent the bonding material 140 from making contact with the connecting portion 433.

<Configuration of Piezoelectric Device 600>

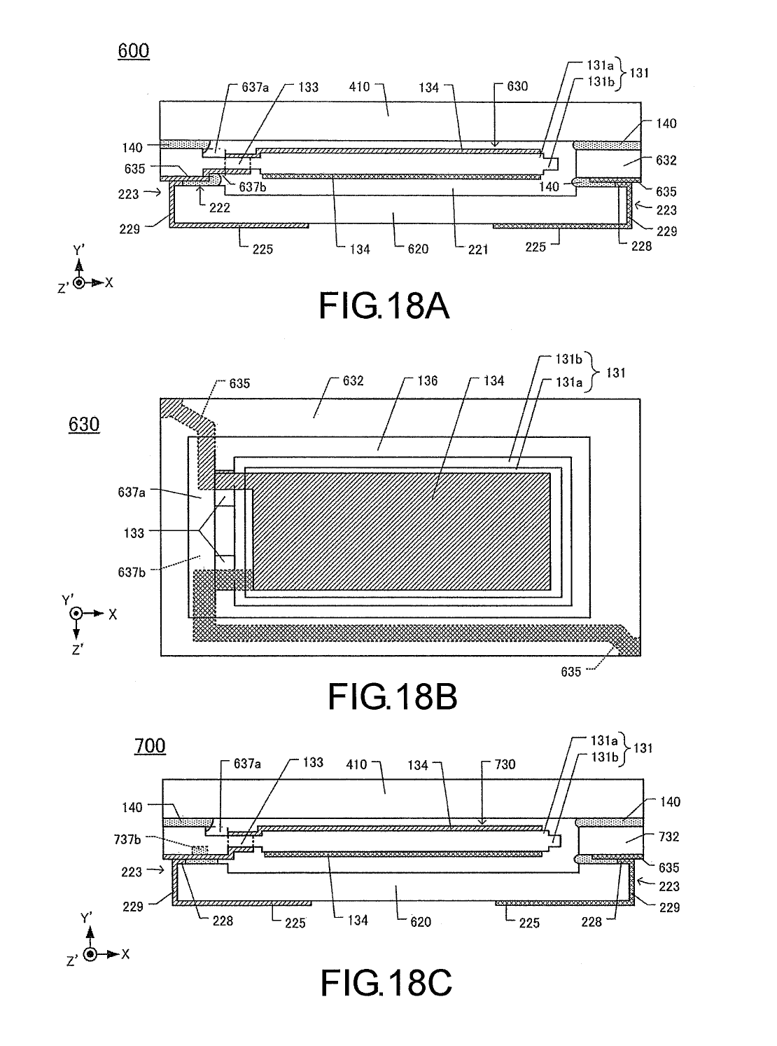

FIG. 18A is a cross-sectional view illustrating a piezoelectric device 600. FIG. 18A is a cross-sectional view taken along the line D-D of FIG. 14 for illustrating the piezoelectric device 600. The piezoelectric device 600 includes a lid plate 410, a base plate 620, and a piezoelectric element 630. The base bonding face 222 and the base hollow portion 221 hollowed in the −Y′-axis direction from the base bonding face 222 are formed in the +Y′-axis side face of the base plate 620. The trench is not formed in the base plate 620. The piezoelectric element 630 includes the excitation portion 131 (refer to FIG. 3A), the frame 632, and the connecting portion 133. The trenches 637a and the 637b are formed in the area adjoining the connecting portions 133 of the +Y′-axis side face and the −Y′-axis side face, respectively, of the frame 632. In the piezoelectric device 600, since the trenches 637a and 637b are formed in the piezoelectric element 630, it is possible to prevent the bonding material 140 from making contact with the connecting portion 133. In addition, the frame 632 in the portion where the trenches 637a and 637b are formed in the piezoelectric element 630 has the same thickness as that of the connecting portion 133 or the circumferential area 131b. Therefore, the trenches 637a and 637b, the connecting portion 133, and the circumferential area 131b can be formed simultaneously.

FIG. 18B is a top plan view illustrating the piezoelectric element 630. In the piezoelectric element 630, the excitation portion 131 and the frame 632 are connected to each other with a pair of connecting portions 133. The perforated trench 136 penetrating the piezoelectric element 630 in the Y′-axis direction is formed in the area other than the connecting portion 133 between the excitation portion 131 and the frame 632. The trench 637a formed in the area adjoining the connecting portion 133 in the +Y′-axis side face of the frame 632 and the trench 637b formed in the area adjoining the connecting portion 133 in the −Y′-axis side face have the same width as the Z′-axis directional width of the perforated trench 136. In addition, the trenches 637a and 637b overlap with each other in the Y-axis direction. In the piezoelectric element 630, a part of the extraction electrode 635 formed in the −Y′-axis side of the frame 632 is extracted to the corner of the frame 632 through the trench 637b.

<Configuration of Piezoelectric Device 700>

FIG. 18C is a cross-sectional view illustrating the piezoelectric device 700. The piezoelectric device 700 includes a piezoelectric element 730, a lid plate 410, and a base plate 620. The piezoelectric element 730 includes an excitation portion 131, a frame 732, and a connecting portion 133. A trench 637a is formed in the +Y′-axis side face of the frame 732, and a trench 737b is formed in the −Y′-axis side face. The trench 737b does not overlap with the trench 637a in the Y-axis direction and is formed in the −X-axis side from the trench 637a. In addition, similar to the trench 637b, the trench 737b has the same width as the Z′-axis directional width of the perforated trench 136. In the piezoelectric device 700, the bonding material 140 applied between the lid plate 410 and the piezoelectric element 730 is intruded into the trench 637a, and the bonding material 140 applied between the base plate 410 and the piezoelectric element 730 is intruded into the trench 737b, so that it is possible to prevent the bonding material 140 from making contact with the connecting portion 133. In addition, the face perpendicular to the Y′-axis in the trench 637a and the +Y′-axis side faces of the connecting portion 133 and the circumferential area 131b are formed in the same plane, and the face perpendicular to the Y′-axis of the trench 737b and the −Y′-axis side faces of the connecting portion 133 and the circumferential area 131b are formed in the same plane. Therefore, the trenches 637a and 737b, the connecting portion 133, and the circumferential area 131b can be formed simultaneously.

<Configuration of Piezoelectric Device 800>

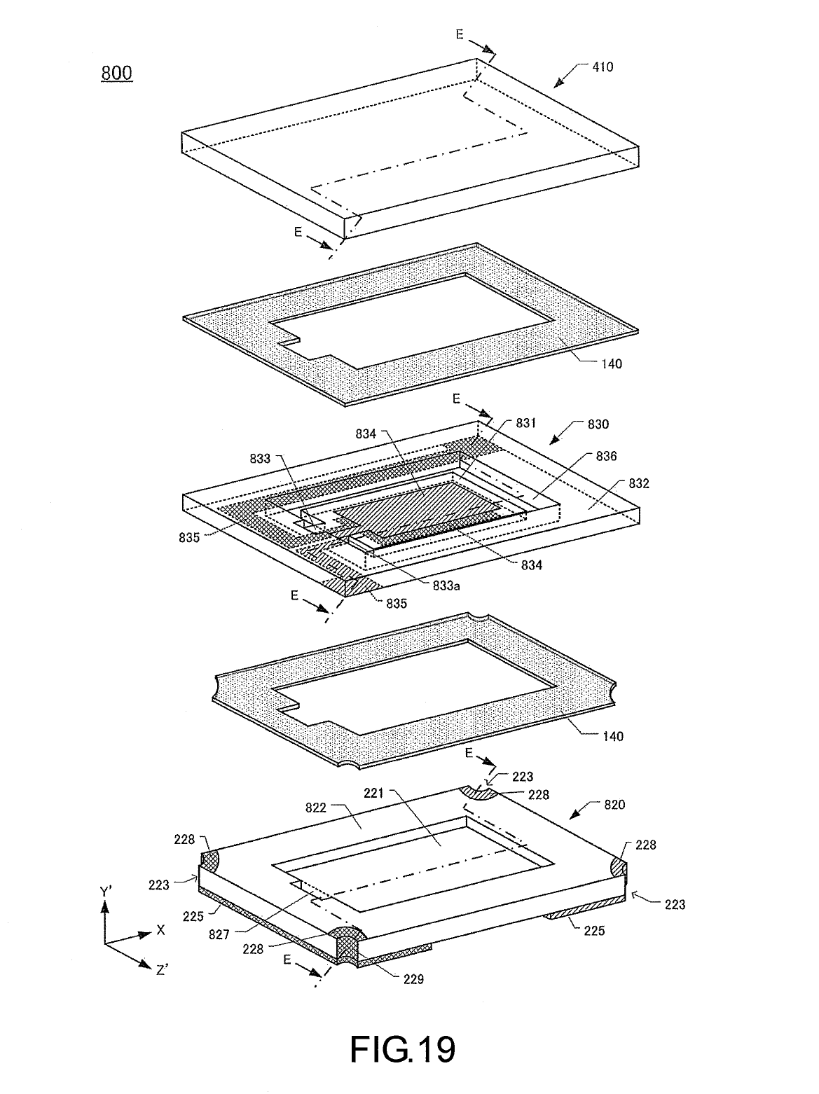

FIG. 19 is an exploded perspective view illustrating the piezoelectric device 800. The piezoelectric device 800 includes a lid plate 410, a base plate 820, and a piezoelectric element 830.

The piezoelectric element 830 includes: an excitation portion 831 which vibrates at a predetermined frequency; a frame 832 surrounding the circumference of the excitation portion 831; and a single connecting portion 833 that connects the frame 832 and the excitation portion 831. The single connecting portion 833 is connected to the −X-axis side of the excitation portion 831, extends in parallel with the X-axis direction, and is connected to the frame 832. In addition, a perforated trench 836 penetrating the piezoelectric element 830 in the Y′-axis direction is formed in the area other than the connecting portion 833 between the excitation portion 831 and the frame 832. In addition, the excitation electrode 834 is formed in each of the +Y′-axis side face and the −Y′-axis side face of the excitation portion 831. The extraction electrode 835 is extracted from the excitation electrode 834 to the corner of the frame 832.

The base plate 820 is formed in a rectangular shape having a long side extending in the X-axis direction and a short side extending in the Z′-axis direction. The −Y′-axis side face of the base plate 820 is a mounting face where the external electrode 125 as an electrode for electrical connection to the print board and the like through soldering is formed. The bonding material 140 is applied to the base bonding face 822, which is the +Y′-axis side face of the base plate 820, bonded to the −Y′-axis side face of the frame 832 of the piezoelectric element 830. In addition, the base hollow portion 221 hollowed in the −Y′-axis direction from the base bonding face 822 is formed in the base plate 820, and the castellated portion 223 castellated to the inside of the base plate 820 is formed in the lateral faces of four corners of the base plate 820. The connection electrode 228 electrically connected to the extraction electrode 835 of the piezoelectric element 830 is formed in the area adjoining the castellated portion 223 of the base bonding face 822. In addition, the lateral electrode 229 is formed in the castellated portion 223 and is electrically connected to the external electrode 225 and the connection electrode 228. Furthermore, the trench 827 hollowed from the base bonding face 822 is formed in the vicinity of a single connecting portion 833 of the piezoelectric element 830 in the base bonding face 822 of the −X-axis side of the base hollow portion 221.

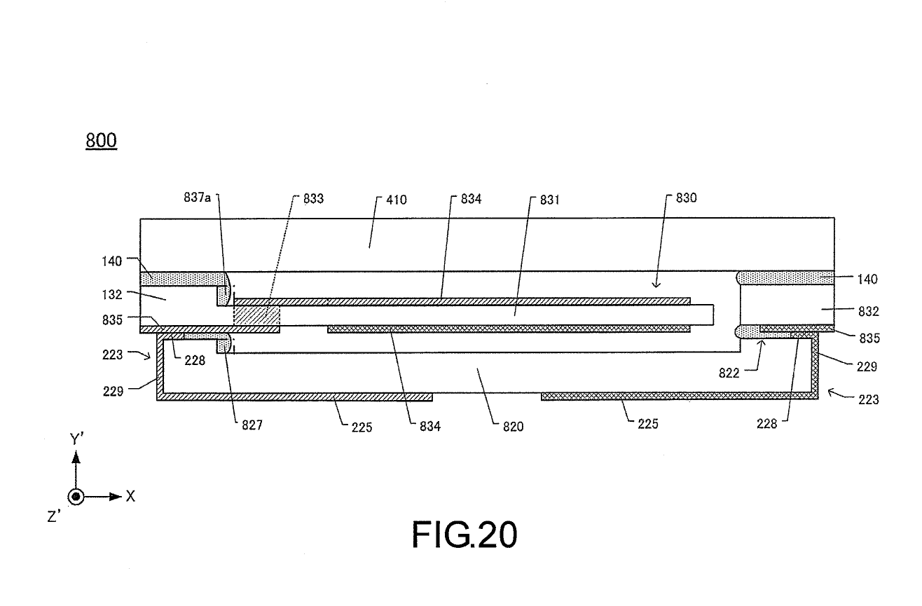

FIG. 20 is a cross-sectional view taken along a line E-E of FIG. 19. In the piezoelectric element 830, the excitation portion 831, the connecting portion 833, and the frame 832 have the same Y′-axis directional thickness in the area where the trench 837a is formed. For this reason, the areas where the trench 837a is formed in the excitation portion 831, the connecting portion 833, and the frame 832 can be formed simultaneously. In the base plate 820, the lateral electrode 229 formed in the lateral face of the castellated portion 223 is electrically connected to the connection electrode 228 formed in the base bonding face 822 and the external electrode 125 formed in the mounting face. In addition, the connection electrode 228 is electrically connected to the extraction electrode 835, so that the external electrode 125 is electrically connected to the excitation electrode 835. Furthermore, the depth of the trench 827 formed in the base bonding face 822 is equal to the depth of the base hollow portion 221 of the base plate 820. For this reason, the trench 827 and the base hollow portion 221 can be formed simultaneously in the process of forming the base hollow portion 221. In the piezoelectric device 800, the bonding material 140 applied between the lid plate 410 and the piezoelectric element 830 is intruded into the trench 837a, and the bonding material 140 applied between the base plate 410 and the piezoelectric element 830 is intruded into the trench 837b, so that it is possible to prevent the bonding material 140 from making contact with the connecting portion 833.

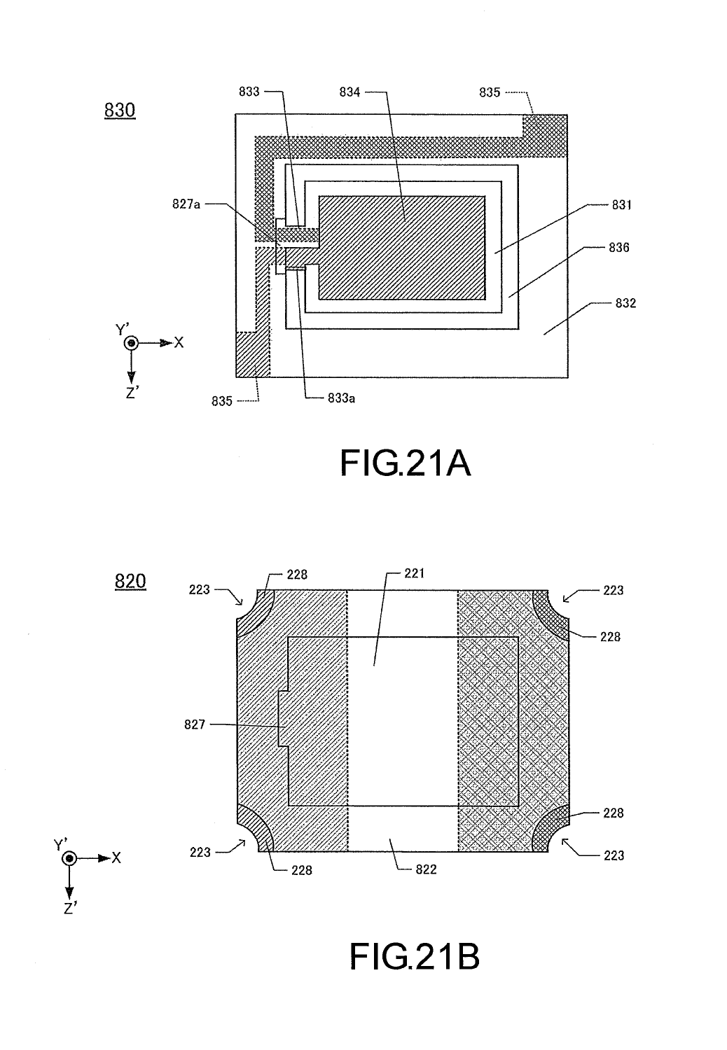

FIG. 21A is a top plan view illustrating the piezoelectric element 830. In the piezoelectric element 830, a single connecting portion 833 is connected to the center of the −X-axis side of the excitation portion 831. In addition, the connecting portion 833 extends in the −X-axis direction from the excitation portion 831 and is connected to the frame 832. The trench 827a is formed around the +Y′-axis side face of the frame 832 where the connecting portion 833 is connected. The Z′-axis directional length of the trench 827a is longer than the Z′-axis directional width of the connecting portion 833. The excitation electrode 834 is formed in the +Y′-axis side face and the −Y′-axis side face of the excitation portion 831, and the extraction electrode 835 is extracted from each excitation electrode 834. The extraction electrode 835 extracted from the excitation electrode 834 formed in the +Y′-axis side face is extracted to the +Z′-axis side corner of the frame 832 in the −X-axis side through the +Y′-axis side face of the connecting portion 833, the lateral face 833a of the +Z′-axis side, and the −Y′-axis side face. In addition, the extraction electrode 835 extracted from the excitation electrode 834 formed in the −Y′-axis side face is extracted to the frame 832 through the −Y′-axis side face of the connecting portion 833, further extends in the −Z′-axis direction and the +X-axis direction up to the −Z′-axis side corner in the +X-axis side.

FIG. 21B is a top plan view illustrating the base plate 820. The castellated portions 223 are formed in the lateral faces of four corners of the base plate 820, and the lateral electrode 229 (refer to FIG. 20) is formed in the castellated portion 223. In addition, the external electrode 225 is formed in each of the +X-axis side and the −X-axis side of the −Y′-axis side face of the base plate 820, and the connection electrode 228 is formed around the castellated portion 223 of the base bonding face 822. The trench 827 adjoining the base hollow portion 221 is formed in the base bonding face 822 in the center of the −X-axis side of the base hollow portion 221. The Z′-axis directional length of the trench 827 is longer than the Z′-axis directional width of the connecting portion 833. The frame 827 is formed to overlap with the −Y′-axis side of the trench 827a formed in the piezoelectric element 830 to prevent the bonding material 140 from making contact with the connecting portion 833.

In the piezoelectric device described above, one or two connecting portions may be provided to connect one side of the excitation portion and the frame.

In the piezoelectric device described above, the bonding material in the vicinity of the connecting portion may be intruded into the trench so as not to extend up to the connecting portion exceeding the trench.

In the piezoelectric device described above, the base plate may be formed of glass or a piezoelectric material where a pair of castellated portions inwardly castellated on a lateral face from the mounting face to the base bonding face are formed, and a pair of the castellated portions may have a first face outwardly extending from the mounting face to the base bonding face side and a second face outwardly extending from the base bonding face to the mounting face, the second face having an area smaller than that of the first face.

In the piezoelectric device described above, a depth of the trench formed in the base plate may be equal to a depth of the castellated portion formed in the first face or a depth of the castellated portion formed in the second face.

In the piezoelectric device described above, a pair of the castellated portions may have a projecting face between the first and second faces, and the projecting face may project to an external side of the base plate with respect to the first and second faces.

In the piezoelectric device described above, the base plate may have base hollow portion hollowed from the base bonding face, and the base hollow portion and the trench may be integrated into a single body.

In the piezoelectric device described above, the lid plate may have a lid hollow portion hollowed from the lid bonding face bonded to the other principal face of the frame and the trench, and a depth of the trench of the lid plate may be equal to a depth of the lid hollow portion.

In the piezoelectric device described above, the trench formed in the lid plate and the lid hollow portion may be integrated into a single body.

In the piezoelectric device described above, the excitation portion may have a mesa-structure area and a circumferential area formed around the mesa-structure area, the circumferential area being thinner than the mesa-structure area, the excitation electrode may be formed in the mesa-structure area, and an extraction electrode extracted from the excitation electrode may be formed in the connecting portion and the frame.

In the piezoelectric device described above, a depth of the trench formed in the frame may be equal to a height difference between the mesa-structure area and the circumferential area.

In the piezoelectric device described above, a surface roughness of the mesa-structure area may be equal to or lower than 100 angstroms.

In the method described above, in a process of preparing the lid wafer, a lid hollow portion hollowed from a lid bonding face bonded to the other principal face of the frame may be formed in the lid plate, and a depth of the trench of the lid plate may be equal to a depth of the lid hollow portion.

In the method described above, in a process of preparing the piezoelectric wafer, a mesa-structure area and a circumferential area formed around the mesa-structure area may be formed in the excitation portion, the circumferential area being thinner than the mesa-structure area, and a depth of the trench formed in the frame may be equal to a height difference between the mesa-structure area and the circumferential area.

In the method described above, in a process of preparing the base wafer, a pair of castellated portions inwardly castellated on a lateral face from the mounting face to the base bonding face may be formed in the base plate, a first face outwardly extending from the mounting face to the base bonding face side and a second face outwardly extending from the base bonding face to the mounting face may be formed in a pair of the castellated portions, the second face having an area smaller than that of the first face, and a depth of the trench formed in the base plate may be equal to a depth of the castellated portion where the first face is formed or a depth of the castellated portion where the second face is formed.

According to this disclosure, it is possible to provide a piezoelectric device having a trench for preventing the bonding material from making contact with the connecting portion and a method of manufacturing the piezoelectric device.

While best modes or embodiments of the invention have been described in detail hereinbefore, those skilled in the art will be appreciated that variations and changes may be made without departing from the scope or spirit of the present invention.

For example, the trench may be formed in the piezoelectric element 230 (refer to FIG. 14) in which the excitation portion, the frame, and the connecting portion have the same thickness. That is, in the process of manufacturing the piezoelectric element, the lid plate, and the base plate, a process of forming the trench may be added to form the trench.

While description has been made by assuming that the piezoelectric element is an AT-cut crystal device in the aforementioned embodiments, the piezoelectric element may be a BT-cut crystal device vibrating in a thickness-shear mode, a tuning fork type crystal device, and the like. Furthermore, the piezoelectric element described above may basically include various piezoelectric materials such as lithium tantalate, lithium niobate, or piezoelectric ceramic as well as the crystal material.

What is claimed is:

1. A piezoelectric device comprising:
a piezoelectric element formed of a piezoelectric material in a rectangular shape, the piezoelectric element having
a rectangular excitation portion having an excitation electrode,
a frame surrounding a circumference of the excitation portion,
a connecting portion connecting one side of the rectangular excitation portion and the frame with a predetermined width;
a base plate having a mounting face where a pair of external electrodes electrically connected to the excitation electrode are formed and a base bonding face bonded to a first principal face of the frame;
a lid plate bonded to a second principal face of the frame; and
a bonding material applied in a paste state between the base plate and the frame and between the lid plate and the frame and then cured to bond the base plate, the frame, and the lid plate,
wherein a trench having a length equal to or more than the predetermined width of the connecting portion is formed in a vicinity of the connecting portion in at least one of the frame, the base plate, and the lid plate.

2. The piezoelectric device according to claim 1, wherein one or two connecting portions are provided to connect one side of the excitation portion and the frame.

3. The piezoelectric device according to claim 1, wherein the bonding material in the vicinity of the connecting portion is intruded into the trench so as not to extend up to the connecting portion exceeding the trench.

4. The piezoelectric device according to claim 1, wherein the base plate is formed of glass or a piezoelectric material where a pair of castellated portions inwardly castellated on a lateral face from the mounting face to the base bonding face are formed, and
a pair of the castellated portions have a first face outwardly extending from the mounting face to the base bonding face side and a second face outwardly extending from the base bonding face to the mounting face, the second face having an area smaller than that of the first face.

5. The piezoelectric device according to claim 4, wherein a depth of the trench formed in the base plate is equal to a depth of the castellated portion where the first face is formed and a depth of the castellated portion where the second face is formed.

6. The piezoelectric device according to claim 4, wherein a pair of the castellated portions has a projecting face between the first and second faces, and the projecting face projects to an external side of the base plate with respect to the first and second faces.

7. The piezoelectric device according to claim 1, wherein the base plate has a base hollow portion hollowed from the base bonding face, and the base hollow portion and the trench are integrated into a single body.

8. The piezoelectric device according to claim 1, wherein the lid plate has a lid hollow portion hollowed from a lid bonding face bonded to the second principal face of the frame and the trench, and a depth of the trench of the lid plate is equal to a depth of the lid hollow portion.

9. The piezoelectric device according to claim 8, wherein the trench formed in the lid plate and the lid hollow portion are integrated into a single body.

10. The piezoelectric device according to claim 1, wherein the excitation portion has a mesa-structure area and a circumferential area formed around the mesa-structure area, the circumferential area being thinner than the mesa-structure area,
the excitation electrode is formed in the mesa-structure area, and
an extraction electrode extracted from the excitation electrode is formed in the connecting portion and the frame.

11. The piezoelectric device according to claim 10, wherein a depth of the trench formed in the frame is equal to a height difference between the mesa-structure area and the circumferential area.

12. The piezoelectric device according to claim 10, wherein a surface roughness of the mesa-structure area is equal to or lower than 100 angstroms.

13. A method of manufacturing a piezoelectric device, comprising:
preparing a piezoelectric wafer having a plurality of piezoelectric elements formed of a piezoelectric material in a rectangular shape, the piezoelectric element having a rectangular excitation portion having an excitation electrode, a frame surrounding a circumference of the excitation portion, a connecting portion connecting one side of the rectangular excitation portion and the frame with a predetermined width;
preparing a base wafer having a plurality of base plates, the base plate having a mounting face where a pair of external electrodes electrically connected to the excitation electrode are formed and a base bonding face bonded to a first principal face of the frame;
preparing a lid wafer having a plurality of lid plates bonded to a second principal face of the frame; and
bonding the base wafer, the piezoelectric wafer, and the lid wafer by applying a bonding material for bonding the base wafer, the piezoelectric wafer, and the lid wafer in a paste state between the base wafer and the piezoelectric wafer and between the lid wafer and the piezoelectric wafer,
wherein a trench having a length equal to or more than the predetermined width of the connecting portion is formed in the vicinity of the connecting portion in at least one of the frame, the base plate, and the lid plate.

14. The method of manufacturing a piezoelectric device according to claim 13, wherein, in a process of preparing the lid wafer, a lid hollow portion hollowed from a lid bonding face bonded to the second principal face of the frame is formed in the lid plate, and
a depth of the trench of the lid plate is equal to a depth of the lid hollow portion.

15. The method of manufacturing a piezoelectric device according to claim 13, wherein, in a process of preparing the piezoelectric wafer, a mesa-structure area and a circumferential area formed around the mesa-structure area are formed in the excitation portion, the circumferential area being thinner than the mesa-structure area, and
a depth of the trench formed in the frame is equal to a height difference between the mesa-structure area and the circumferential area.

16. The method of manufacturing a piezoelectric device according to claim 13, wherein, in a process of preparing the base wafer, a pair of castellated portions inwardly castellated on a lateral face from the mounting face to the base bonding face are formed in the base plate,
a first face outwardly extending from the mounting face to the base bonding face side and a second face outwardly extending from the base bonding face to the mounting face are formed in the pair of the castellated portions, the second face having an area smaller than that of the first face, and
a depth of the trench formed in the base plate is equal to a depth of the castellated portion where the first face is formed or a depth of the castellated portion where the second face is formed.
